(19) United States
(12) Patent Application Publication
(10) Pub. No.: US 2026/0282641 A1
(43) Pub. Date: Sep. 17, 2026

(54) LIGHT DETECTING DEVICE

(71) Applicant: Sony Semiconductor Solutions Corporation, Kanagawa (JP)

(72) Inventors: Yusuke SATO, Kanagawa (JP); Tetsuji YAMAGUCHI, Kanagawa (JP); Hideaki TOGASHI, Kanagawa (JP); Yosuke SUDA, Kanagawa (JP)

(21) Appl. No.: 19/168,548

(22) PCT Filed: Aug. 2, 2024
(86) PCT No.: PCT/JP2024/027808

§ 371 Date: Sep. 24, 2025

(30) Foreign Application Priority Data
Aug. 4, 2023 (JP) 2023-127686
Jan. 24, 2024 (JP) 2024-008658

(51) Int. Cl. H10K 39/32; H04N 25/17; H04N 25/20; H04N 25/40; H04N 25/707; H04N 25/77; H10K 39/00; H10K 39/38

(52) U.S. Cl. CPC H10K 39/32; H04N 25/17; H04N 25/20; H04N 25/41; H04N 25/707; H04N 25/77; H10K 39/38; H10K 39/401

(57) ABSTRACT

A light detecting device is provided and includes a semiconductor substrate; and a pixel including an event signal generation circuit and a first photoelectric conversion circuit, wherein the first photoelectric conversion circuit is configured to perform photoelectric conversion of incident light to generate a first charge based on a first change in luminance of the incident light, and the event signal generation circuit is configured to detect the change in luminance based on the first charge and generate an event signal based on the first change.

### TECHNICAL FIELD

The present disclosure relates to a light detecting device.

### BACKGROUND ART

As a light detecting device that images a subject, a light detecting device in which pixels including photodiodes and transistors formed in a semiconductor substrate is used. For example, a solid-state imaging device has been proposed in which a photodiode is formed in a semiconductor substrate and a semiconductor region constituting the photodiode is extended to a lower side of a transistor to improve transfer of a charge from the photodiode to the transistor (see, for example, PTL 1).

### CITATION LIST

### Patent Literature

PTL 1: Japanese Laid-open Patent Publication No. 2005-223084

### SUMMARY OF INVENTION

### Technical Problem

At the time of generating moving image data from images generated by the light detecting device described above, a system that reduces the data amount by updating only an image of a region where a subject moves is used. However, in order to detect a movement of a subject using the light detecting device of the related art described above, it is necessary to calculate a difference between two consecutive images, and there is a problem that it is difficult to detect a moving object at a high speed.

Therefore, the present disclosure proposes a light detecting device that detects a movement of a subject at a high speed.

### Solution to Problem

A first aspect of the present disclosure is a light detecting device including a semiconductor substrate; and a pixel including an event signal generation circuit and a first photoelectric conversion circuit, wherein the first photoelectric conversion circuit is configured to perform photoelectric conversion of incident light to generate a first charge based on a first change in luminance of the incident light, and the event signal generation circuit is configured to detect the change in luminance based on the first charge and generate an event signal based on the first change.

A second aspect of the present disclosure is a light detecting device including a semiconductor substrate; and
a first photoelectric conversion circuit disposed in the semiconductor substrate or stacked on the semiconductor substrate; wherein the first photoelectric conversion circuit is configured to output a signal for a gradation signal or an event signal switchably.

### BRIEF DESCRIPTION OF DRAWINGS

FIG. 1 is a diagram illustrating an example of a schematic configuration of a light detecting device according to an embodiment of the present disclosure.

FIG. 2 is a diagram illustrating an example of a configuration of a pixel according to a first embodiment of the present disclosure.

FIG. 3 is a diagram illustrating an example of a configuration of a gradation signal generation unit according to an embodiment of the present disclosure.

FIG. 4 is a diagram illustrating an example of a configuration of an event signal generation unit according to the first embodiment of the present disclosure.

FIG. 5 is a circuit diagram illustrating an example of a configuration of an event signal generation unit according to an embodiment of the present disclosure.

FIG. 6 is a circuit diagram illustrating an example of a configuration of an event signal generation unit according to an embodiment of the present disclosure.

FIG. 7 is a cross-sectional view illustrating an example of a configuration of a pixel according to the first embodiment of the present disclosure.

FIG. 8 is a cross-sectional view illustrating an example of a configuration of a pixel according to a second embodiment of the present disclosure.

FIG. 9 is a cross-sectional view illustrating an example of a configuration of a pixel according to a third embodiment of the present disclosure.

FIG. 10 is a diagram illustrating an example of a configuration of an element according to the third embodiment of the present disclosure.

FIG. 11 is a circuit diagram illustrating examples of configurations of a gradation signal generation unit and an event signal generation unit according to a fourth embodiment of the present disclosure.

FIG. 12 is a cross-sectional view illustrating an example of a configuration of a pixel according to the fourth embodiment of the present disclosure.

FIG. 13 is a plan view illustrating an example of a configuration of an element according to the fourth embodiment of the present disclosure.

FIG. 14 is a diagram illustrating an example of a configuration of an element according to the fourth embodiment of the present disclosure.

FIG. 15 is a circuit diagram illustrating examples of other configurations of a gradation signal generation unit and an event signal generation unit according to the fourth embodiment of the present disclosure.

FIG. 16 is a circuit diagram illustrating examples of other configurations of a gradation signal generation unit and an event signal generation unit according to the fourth embodiment of the present disclosure.

FIG. 17 is a circuit diagram illustrating examples of configurations of a gradation signal generation unit and an event signal generation unit according to a fifth embodiment of the present disclosure.

FIG. 18 is a cross-sectional view illustrating an example of a configuration of a pixel according to the fifth embodiment of the present disclosure.

FIG. 19 is a circuit diagram illustrating examples of other configurations of a gradation signal generation unit and an event signal generation unit according to the fifth embodiment of the present disclosure.

FIG. 20 is a circuit diagram illustrating examples of other configurations of a gradation signal generation unit and an event signal generation unit according to the fifth embodiment of the present disclosure.

FIG. 21 is a circuit diagram illustrating examples of other configurations of a gradation signal generation unit and an event signal generation unit according to a modification of the embodiment of the present disclosure.

FIG. 22 is a cross-sectional view illustrating an example of a configuration of a pixel according to a modification of the embodiment of the present disclosure.

FIG. 23 is a cross-sectional view illustrating another example of a configuration of a pixel according to a modification of the embodiment of the present disclosure.

FIG. 24 is a diagram illustrating an example of a configuration of a photoelectric conversion unit according to a modification of the embodiment of the present disclosure.

FIG. 25 is a cross-sectional view illustrating an example of a configuration of a pixel according to a seventh embodiment of the present disclosure.

FIG. 26 is a cross-sectional view illustrating an example of another configuration of a pixel according to the seventh embodiment of the present disclosure.

FIG. 27A is a view illustrating an example of a method of manufacturing a light detecting device according to the seventh embodiment of the present disclosure.

FIG. 27B is a view illustrating an example of a method of manufacturing a light detecting device according to the seventh embodiment of the present disclosure.

FIG. 27C is a view illustrating an example of a method of manufacturing a light detecting device according to the seventh embodiment of the present disclosure.

FIG. 27D is a diagram illustrating an example of a method of manufacturing a light detecting device according to the seventh embodiment of the present disclosure.

FIG. 27E is a view illustrating an example of a method of manufacturing a light detecting device according to the seventh embodiment of the present disclosure.

FIG. 27F is a view illustrating an example of a method of manufacturing a light detecting device according to the seventh embodiment of the present disclosure.

FIG. 27G is a view illustrating an example of a method of manufacturing a light detecting device according to the seventh embodiment of the present disclosure.

FIG. 27H is a view illustrating an example of a method of manufacturing a light detecting device according to the seventh embodiment of the present disclosure.

FIG. 27I is a diagram illustrating an example of a method of manufacturing a light detecting device according to the seventh embodiment of the present disclosure.

FIG. 27J is a view illustrating an example of a method of manufacturing a light detecting device according to the seventh embodiment of the present disclosure.

FIG. 27K is a view illustrating an example of a method of manufacturing a light detecting device according to the seventh embodiment of the present disclosure.

FIG. 27L is a view illustrating an example of a method of manufacturing a light detecting device according to the seventh embodiment of the present disclosure.

FIG. 27M is a view illustrating an example of a method of manufacturing a light detecting device according to the seventh embodiment of the present disclosure.

FIG. 27N is a diagram illustrating an example of a method of manufacturing a light detecting device according to the seventh embodiment of the present disclosure.

FIG. 27O is a view illustrating an example of a method of manufacturing a light detecting device according to the seventh embodiment of the present disclosure.

FIG. 27P is a view illustrating an example of a method of manufacturing a light detecting device according to the seventh embodiment of the present disclosure.

FIG. 28 is a cross-sectional view illustrating an example of a configuration of a pixel according to an eighth embodiment of the present disclosure.

FIG. 29 is a cross-sectional view illustrating an example of another configuration of a pixel according to the eighth embodiment of the present disclosure.

FIG. 30 is a cross-sectional view illustrating an example of another configuration of a pixel according to the eighth embodiment of the present disclosure.

FIG. 31 is a cross-sectional view illustrating an example of a configuration of a pixel according to a ninth embodiment of the present disclosure.

FIG. 32 is a cross-sectional view illustrating an example of another configuration of a pixel according to the ninth embodiment of the present disclosure.

FIG. 33 is a cross-sectional view illustrating an example of another configuration of a pixel according to the ninth embodiment of the present disclosure.

FIG. 34 is a diagram illustrating an example of a configuration of a current-voltage conversion circuit according to a modification of the embodiment of the present disclosure.

FIG. 35 is a diagram illustrating an example of a configuration of a current-voltage conversion circuit according to a modification of the embodiment of the present disclosure.

FIG. 36 is a diagram illustrating an example of a configuration of a current-voltage conversion circuit according to a modification of the embodiment of the present disclosure.

FIG. 37 is a diagram illustrating an example of a configuration of a current-voltage conversion circuit according to a modification of the embodiment of the present disclosure.

FIG. 38 is a diagram illustrating an example of a configuration of a current-voltage conversion circuit according to a modification of the embodiment of the present disclosure.

FIG. 39 is a diagram illustrating an example of a configuration of a current-voltage conversion circuit according to a modification of the embodiment of the present disclosure.

FIG. 40 is a diagram illustrating an example of generation of a gradation signal and an event signal according to an embodiment of the present disclosure.

FIG. 41 is a block diagram illustrating an example of a configuration of an imaging device mounted on an electronic device.

FIG. 42 is a block diagram depicting an example of schematic configuration of a vehicle control system as an example of a mobile body control system to which the technology according to an embodiment of the present disclosure can be applied.

FIG. 43 is a diagram illustrating an example of an installation position of an imaging unit.

FIG. 44 is a view depicting an example of a schematic configuration of an endoscopic surgery system to which the technology according to an embodiment of the present disclosure (present technology) can be applied.

FIG. 45 is a block diagram illustrating an example of functional configurations of a camera head and a CCU illustrated in FIG. 44.

### DESCRIPTION OF EMBODIMENTS

Hereinafter, embodiments of the present disclosure will be described in detail with reference to the drawings. The description will be given in the following order. Note that, in the following embodiments, the same parts will be denoted by the same reference signs, and redundant description will be omitted.
1. First Embodiment
2. Second Embodiment
3. Third Embodiment
4. Fourth Embodiment
5. Fifth Embodiment
6. Sixth Embodiment
7. Seventh Embodiment
8. Eighth Embodiment
9. Ninth Embodiment
10. Others
11. Configuration of Electronic Device
12. Example of Application to Mobile Body
13. Example of Application to Endoscopic Surgery System

### 1. First Embodiment

### <Configuration of Light Detecting Device>

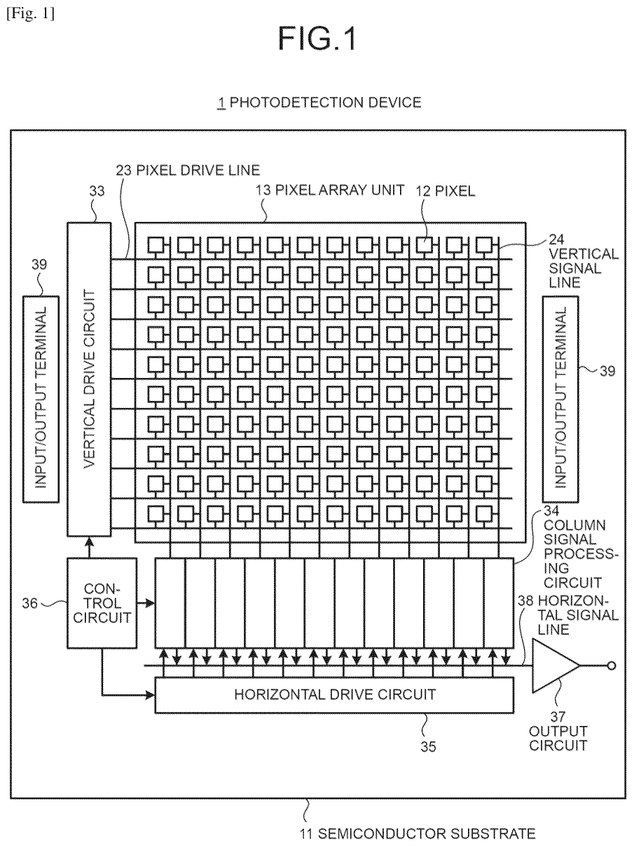

FIG. 1 is a diagram illustrating an example of a schematic configuration of a light detecting device according to an embodiment of the present disclosure. As illustrated in FIG. 1, the light detecting device 1 in the present example includes a pixel array unit (a so-called imaging region) 13 in which pixels 12 including a plurality of photoelectric conversion units are regularly and two-dimensionally arranged on a semiconductor substrate 11, e.g., a silicon substrate, and a peripheral circuit unit. The pixel 12 includes, for example, a photodiode serving as a photoelectric conversion unit and a plurality of pixel transistors (so-called MOS transistors). The plurality of pixel transistors can include, for example, three transistors: a transfer transistor, a reset transistor, and an amplification transistor. In addition, a selection transistor may be added to form four transistors. The pixel 12 may have a shared pixel structure. This pixel sharing structure includes a plurality of photodiodes, a plurality of transfer transistors, one shared floating diffusion region, and every other shared pixel transistor.

The peripheral circuit unit includes a vertical drive circuit 33, a column signal processing circuit 34, a horizontal drive circuit 35, an output circuit 37, a control circuit 36, etc.

The control circuit 36 receives an input clock and data instructing an operation mode and the like, and outputs data such as internal information of an imaging element. That is, on the basis of a vertical synchronization signal, a horizontal synchronization signal, and a master clock, the control circuit 36 generates a clock signal and a control signal serving on which the operations of the vertical drive circuit 33, the column signal processing circuit 34, the horizontal drive circuit 35, and the like are based. Then, these signals are input to the vertical drive circuit 33, the column signal processing circuit 34, the horizontal drive circuit 35, and the like.

The vertical drive circuit 33 is constituted by, for example, a shift register, selects a pixel drive line 23, supplies a pulse for driving pixels to the selected pixel drive line, and drives the pixels in units of rows. That is, the vertical drive circuit 33 sequentially selects and scans the pixels 12 of the pixel array unit 13 in the vertical direction in units of rows, and supplies a pixel signal based on a signal charge generated according to the amount of received light in, for example, a photodiode serving as a photoelectric conversion unit of each pixel 12 to the column signal processing circuit 34 through a vertical signal line 24.

The column signal processing circuit 34 is arranged, for example, for each column of the pixels 12, and performs signal processing such as noise removal on a signal output from a pixel 12 of one row for each pixel column. That is, the column signal processing circuit 34 performs signal processing such as correlated double sampling (CDS) for removing fixed pattern noise unique to the pixel 12, signal amplification, and AD conversion. A horizontal selection switch (not illustrated) is provided at an output stage of the column signal processing circuit 34, and is connected between the column signal processing circuit 34 and a horizontal signal line 38.

The horizontal drive circuit 35 is constituted by, for example, a shift register, sequentially selects the column signal processing circuits 34 by sequentially outputting horizontal scanning pulses, so that a pixel signal is output from each of the column signal processing circuits 34 to the horizontal signal line 38.

The output circuit 37 performs signal processing on the signals sequentially supplied from the respective column signal processing circuits 34 through the horizontal signal line 38, and outputs the processed signals. For example, only buffering may be performed, or black level adjustment, column variation correction, various kinds of digital signal processing, and the like may be performed. An input/output terminal 39 exchanges signals with the outside.

### <Configuration of Pixel>

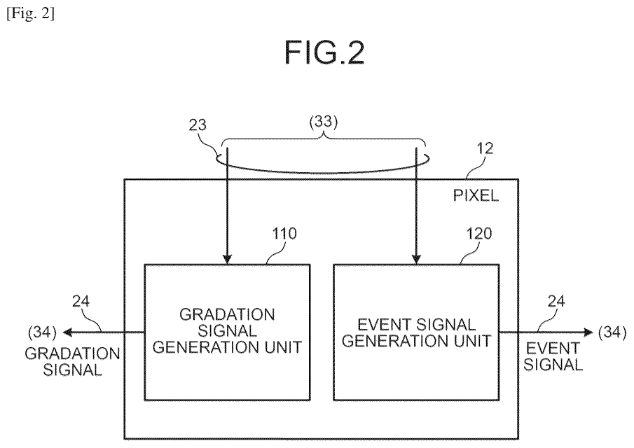

FIG. 2 is a diagram illustrating an example of a configuration of a pixel according to the first embodiment of the present disclosure. FIG. 2 is a block diagram illustrating an example of a configuration of the pixel 12. The pixel 12 includes a gradation signal generation unit 110 and an event signal generation unit 120. The gradation signal generation unit 110 generates a gradation signal that is a signal corresponding to a luminance of incident light on the basis of a charge generated by photoelectric conversion of the photoelectric conversion unit (not illustrated). The gradation signal generation unit 110 generates a gradation signal on the basis of a control signal supplied from the vertical drive circuit 33 via the pixel drive line 23. The generated gradation signal is transmitted to the column signal processing circuit 34 via the vertical signal line 24.

The event signal generation unit 120 detects a change in luminance of incident light in the same direction as an event on the basis of a charge generated by photoelectric conversion of the photoelectric conversion unit (not illustrated), and generates an event signal that is a signal based on the detected event. The event signal generation unit 120 generates an event signal on the basis of a control signal supplied from the vertical drive circuit 33 via the pixel drive line 23. The generated event signal is transmitted to the column signal processing circuit 34 via the vertical signal line 24.

Note that a first photoelectric conversion unit 201 and a second photoelectric conversion unit 202 are further arranged in the pixel 12 of FIG. 2. The gradation signal generation unit 110 of FIG. 2 generates a gradation signal on the basis of a charge generated by photoelectric conversion of the second photoelectric conversion unit 202. Furthermore, the event signal generation unit 120 of FIG. 2 detects an event on the basis of a charge generated by photoelectric conversion of the first photoelectric conversion unit 201.

### <Configuration of Gradation Signal Generation Unit>

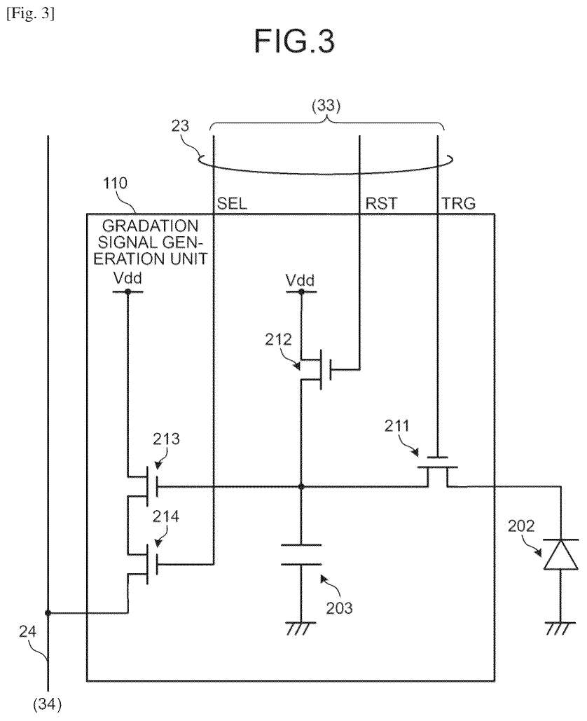

FIG. 3 is a diagram illustrating an example of a configuration of a gradation signal generation unit according to an embodiment of the present disclosure. FIG. 3 is a circuit illustrating an example of a configuration of the gradation signal generation unit 110. Note that the second photoelectric conversion unit 202 is further illustrated in FIG. 3. The gradation signal generation unit 110 includes a charge holding unit 203 and MOS transistors 211 to 214. As the MOS transistors 211 to 214, n-channel MOS transistors can be used. Furthermore, the pixel drive lines 23 connected to the pixel 12 includes a signal line TRG, a signal line RST, and a signal line SEL. Furthermore, power supply lines Vdd for supplying power are wired to the pixel 12.

An anode of the second photoelectric conversion unit 202 is grounded, and a cathode of the second photoelectric conversion unit 202 is connected to a source of the MOS transistor 211. A drain of the MOS transistor 211 is connected to a source of the MOS transistor 212, a gate of the MOS transistor 213, and one end of the charge holding unit 203. The other end of the charge holding unit 203 is grounded. A drain of the MOS transistor 212 is connected to the power supply line Vdd. A drain of the MOS transistor 213 is connected to the power supply line Vdd, and a source of the MOS transistor 213 is connected to a drain of the MOS transistor 214. A source of the MOS transistor 214 is connected to the vertical signal line 24. The signal lines TRG, RST, and SEL are connected to the gates of the MOS transistors 211, 212, and 214, respectively.

The second photoelectric conversion unit 202 is an element that performs photoelectric conversion of incident light. The second photoelectric conversion unit 202 generates and holds a charge by photoelectric conversion. As will be described below, the second photoelectric conversion unit 202 is disposed on a semiconductor substrate 300.

The MOS transistor 211 transfers the charge held in the second photoelectric conversion unit 202 to the charge holding unit 203. The MOS transistor 211 is controlled by a control signal transmitted by the signal line TRG. The MOS transistor 211 corresponds to the above-described transfer transistor.

The charge holding unit 203 is an element that holds a charge. The charge holding unit 203 can be constituted by a semiconductor region formed on the semiconductor substrate.

The MOS transistor 212 resets the charge holding unit 203. The MOS transistor 212 is controlled by a control signal transmitted by the signal line RST. The MOS transistor 212 corresponds to the above-described reset transistor.

The MOS transistor 213 is an element that generates a gradation signal corresponding to the charge held in the charge holding unit 203. The generated gradation signal is output to a source terminal. The MOS transistor 213 corresponds to the above-described amplification transistor.

The MOS transistor 214 is an element that outputs the gradation signal generated by the MOS transistor 213 to the vertical signal line 24. The MOS transistor 214 is controlled by a control signal transmitted by the signal line SEL. The MOS transistor 214 corresponds to the above-described selection transistor.

The generation of the gradation signal in the gradation signal generation unit 110 of FIG. 3 can be performed as follows. First, the MOS transistor 212 is made conductive to reset the charge holding unit 203. At this time, the MOS transistor 211 is made conductive. Accordingly, the second photoelectric conversion unit 202 is also reset. The resetting of the charge holding unit 203 and the second photoelectric conversion unit 202 is an operation corresponding to an electronic shutter. Next, the MOS transistors 211 and 212 are brought into a non-conductive state. Accordingly, exposure is started.

After a predetermined exposure period elapses, the MOS transistor 212 is made conductive to reset the charge holding unit 203. After the resetting of the charge holding unit 203, the MOS transistor 211 is made conductive to transfer a charge of the second photoelectric conversion unit 202 to the charge holding unit 203. Then, a gradation signal is generated by the MOS transistor 213. By making the MOS transistor 214 conductive, the generated gradation signal is output to the vertical signal line 24. The operation of generating the gradation signal after the lapse of the exposure period is referred to as reading.

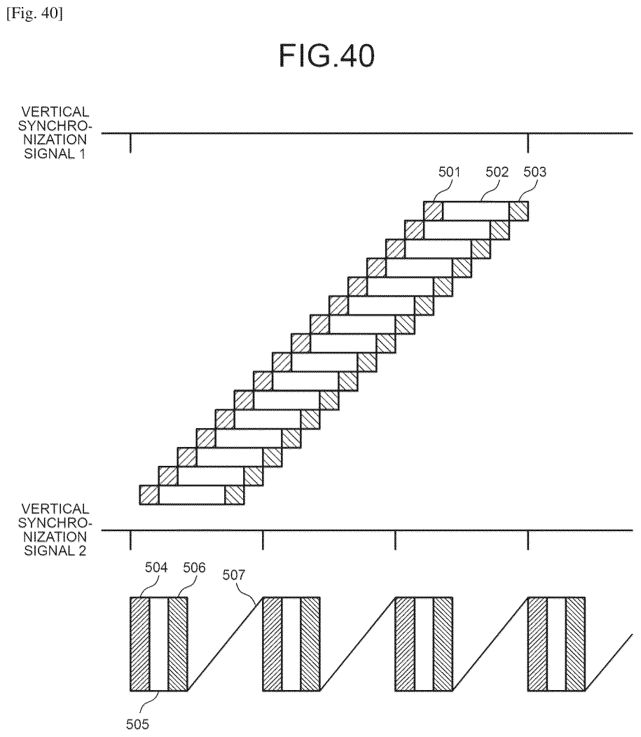

In this manner, the gradation signal is generated by three factors: the electronic shutter, the exposure, and the reading, and is output from the gradation signal generation unit 110. As described above, the generation of the gradation signal is performed for each row. At this time, the shutter, the exposure, and the reading are sequentially applied at staggered timings for each row. This state will be described below with reference to FIG. 40.

### <Configuration of Event Signal Generation Unit>

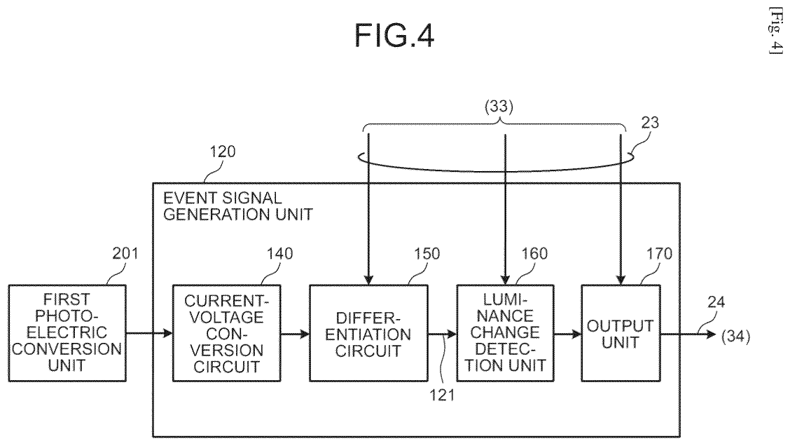

FIG. 4 is a diagram illustrating an example of a configuration of an event signal generation unit according to the first embodiment of the present disclosure. FIG. 4 is a block diagram illustrating an example of a configuration of the event signal generation unit 120. The event signal generation unit 120 in FIG. 4 includes a current-voltage conversion circuit 140, a differentiation circuit 150, a luminance change detection unit 160, and an output unit 170. Note that the first photoelectric conversion unit 201 is further illustrated in FIG. 4.

Similarly to the second photoelectric conversion unit 202, the first photoelectric conversion unit 201 performs photoelectric conversion of incident light. The first photoelectric conversion unit 201 can constituted by a photoelectric conversion film disposed adjacent to the semiconductor substrate 300.

The current-voltage conversion circuit 140 converts a photocurrent from the first photoelectric conversion unit 201 into a voltage signal. In addition, during the conversion, the current-voltage conversion circuit 140 performs logarithmic com-pression on the voltage signal. The converted voltage signal is output to the differentiation circuit 150. The configuration of the current-voltage conversion circuit 140 will be described in detail below.

The differentiation circuit 150 extracts an amount of change in the voltage signal output from the current-voltage conversion circuit 140, and integrates the extracted amount of change to generate a signal corresponding to the amount of change in the voltage signal. This signal corresponds to a signal corresponding to a change in luminance of incident light. This signal is referred to as an optical signal. The differentiation circuit 150 outputs the generated optical signal to the luminance change detection unit 160 through a signal line 121. Further, a control signal is input from the vertical drive circuit 33 to the differentiation circuit 150. The control signal is a signal for resetting the above-described circuit that detects an amount of change in voltage signal. The configuration of the differentiation circuit 150 will be described in detail below.

The luminance change detection unit 160 detects a change in luminance of incident light. The luminance change detection unit 160 in FIG. 4 detects a change in the optical signal output from the differentiation circuit 150 based on a threshold. That is, when the change in the optical signal exceeds the threshold, the change in the optical signal is detected as an event. Here, an event in a direction in which the optical signal increases will be referred to as an on-event, and an event in a direction in which the optical signal decreases will be referred to as an off-event. The luminance change detection unit 160 detects an on-event and an off-event with voltages of an on-event detection signal and an off-event detection signal supplied from the vertical drive circuit 33 as respective thresholds. This detection result is output to the output unit 170. The configuration of the luminance change detection unit 160 will be described in detail below.

The output unit 170 outputs, as event signals, an on-event and an-off event detected by the luminance change detection unit 160 on the basis of a control signal from the vertical drive circuit 33.

### <Circuit Configuration of Event Signal Generation Unit>

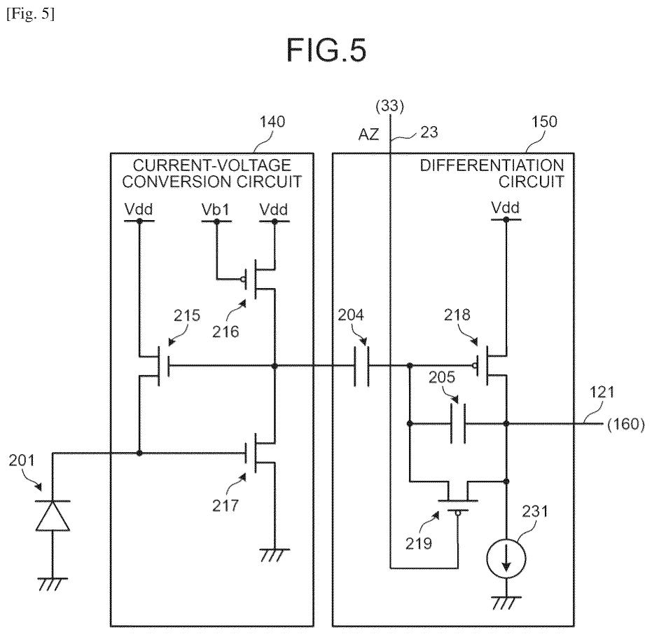

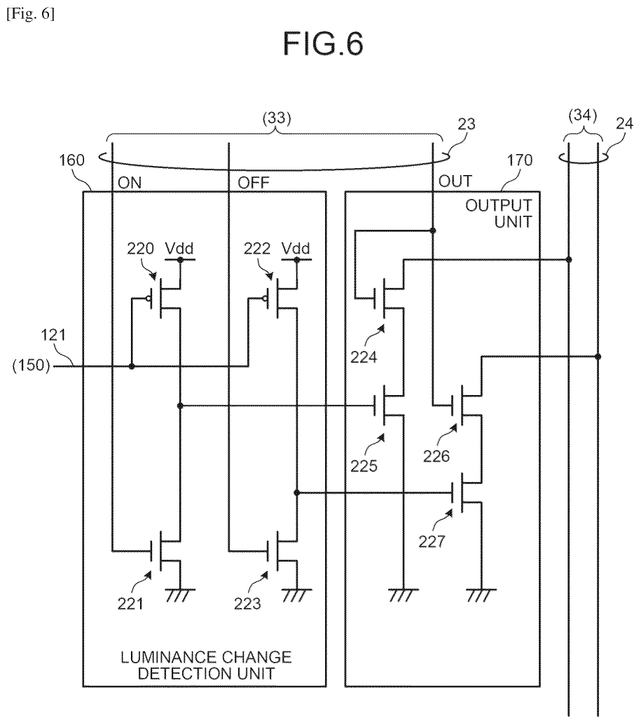

FIGS. 5 and 6 are circuit diagrams illustrating an example of a configuration of the event signal generation unit according to an embodiment of the present disclosure. FIG. 5 is a circuit diagram illustrating examples of configurations of the current-voltage conversion circuit 140 and the differentiation circuit 150. Note that the first photoelectric conversion unit 201 is further illustrated in FIG. 5. FIG. 6 is a circuit diagram illustrating examples of configurations of the luminance change detection unit 160 and the output unit 170.

The current-voltage conversion circuit 140 in FIG. 5 includes MOS transistors 215 to 217. In FIG. 5, Vdd represents a power supply line Vdd that supplies power. Vb1 represents a signal line Vb1 that supplies a bias voltage. As the MOS transistors 215 and 217, n-channel MOS transistors can be used. As the MOS transistor 216, a p-channel MOS transistor can be used.

An anode of the first photoelectric conversion unit 201 is grounded, and a cathode of the first photoelectric conversion unit 201 is connected to a source of the MOS transistor 215 and a gate of the MOS transistor 217. Sources of the MOS transistor 215 and the MOS transistor 216 are connected to the power supply lines Vdd, and a gate of the MOS transistor 216 is connected to the signal line Vb1. A source of the MOS transistor 217 is grounded, and a drain of the MOS transistor 217 is connected to a gate of the MOS transistor 215, a drain of the MOS transistor 216, and an output signal line of the current-voltage conversion circuit 140. One end of a capacitor of the differentiation circuit 150 is connected to the output signal line.

The MOS transistor 215 is a MOS transistor that supplies a current to the first photoelectric conversion unit 201. A sink current (photocurrent) corresponding to incident light flows through the first photoelectric conversion unit 201. The MOS transistor 215 supplies the sink current. At this time, the gate of the MOS transistor 215 is driven by an output voltage of the MOS transistor 217 to be described below, and outputs a source current equal to the sink current of the first photoelectric conversion unit 201. Since a gate-source voltage Vgs of a MOS transistor is a voltage corresponding to the source current, a source voltage of the MOS transistor 215 is a voltage corresponding to the current of the first photoelectric conversion unit 201. As a result, the photocurrent of the first photoelectric conversion unit 201 is converted into a voltage signal.

The MOS transistor 217 is a MOS transistor that amplifies the source voltage of the MOS transistor 215. Furthermore, the MOS transistor 216 constitutes a constant current load of the MOS transistor 217. The amplified voltage signal is output to the drain of the MOS transistor 217. This voltage signal is output to the differentiation circuit 150, and is also fed back to the gate of the MOS transistor 215. When Vgs of the MOS transistor 215 is equal to or lower than a threshold voltage, the source current changes in an exponential manner with respect to the change in Vgs. Therefore, the output voltage of the MOS transistor 217 fed back to the gate of the MOS transistor 215 is a voltage signal obtained by logarithmically compressing the photocurrent of the first photoelectric conversion unit 201 equal to the source current of the MOS transistor 215.

### <Configuration of Differentiation Circuit>

The differentiation circuit 150 of FIG. 5 includes capacitors 204 and 205, MOS transistors 218 and 219, and a constant current circuit 231. As the MOS transistors 218 and 219, p-channel MOS transistors can be used.

As described above, an output of the current-voltage conversion circuit 140 is connected to one end of the capacitor 204, and the other end of the capacitor 204 is connected to a gate of the MOS transistor 218, a drain of the MOS transistor 219, and one end of the capacitor 205. The other end of the capacitor 205 is connected to a drain of the MOS transistor 218, a drain of the MOS transistor 219, a sink-side terminal of the constant current circuit 231, and the signal line 121. A source of the MOS transistor 218 is connected to a power supply line Vdd, and a gate of the MOS transistor 219 is connected to a signal line AZ. A source-side terminal of the constant current circuit 231 is grounded.

The capacitor 204 corresponds to a coupling capacitor. The capacitor 204 blocks a DC component of the output voltage of the current-voltage conversion circuit 140 and allows only an AC component of the output voltage of the current-voltage conversion circuit 140 to pass therethrough. In addition, a current based on a change in the output voltage of the current-voltage conversion circuit 140 is supplied to the gate of the MOS transistor 218 via the capacitor 204. The AC component of the output voltage of the current-voltage conversion circuit 140 corresponds to a change in photocurrent. The MOS transistor 218 and the constant current circuit 231 constitute an inverting amplifier circuit. A change in the output voltage of the current-voltage conversion circuit 140 is input to the gate of the MOS transistor 218 via the capacitor 204, is inverted and amplified by the MOS transistor 218, and is output to the drain of the MOS transistor 218. Therefore, a current based on a change in the output voltage of the current-voltage conversion circuit 140 flows through the capacitor 205, such that the capacitor 205 is charged and discharged. That is, the change in the output voltage of the current-voltage conversion circuit 140 is added up (integrated). An optical signal that is a signal corresponding to the amount of change in the voltage signal output from the current-voltage conversion circuit 140 is output to the signal line 121.

The MOS transistor 219 resets the differentiation circuit 150. Both ends of the capacitor 205 are short-circuited by making the MOS transistor 219 conductive. The integrated change in the output voltage of the current-voltage conversion circuit 140 is discharged and reset. By the reset, the output voltage of the differentiation circuit 150 becomes, for example, a voltage at the midpoint between the power supply line Vdd and the ground line. The reset is controlled by an AZ control signal transmitted by the signal line AZ. Hereinafter, the reset of the differentiation circuit 150 will be referred to as an AZ operation.

### <Configuration of Luminance Change Detection Unit>

In FIG. 6, the luminance change detection unit 160 includes MOS transistors 220 to 223. As the MOS transistors 220 and 222, p-channel MOS transistors can be used. Furthermore, as the MOS transistors 221 and 223, n-channel MOS transistors can be used. In addition, signal lines ON and OFF from the vertical drive circuit 33 are connected to the luminance change detection unit 160. The signal line ON is a signal line that transmits an on-event detection signal. The signal line OFF is a signal line that transmits an off-event detection signal.

The signal line 121 is connected to a gate of the MOS transistor 220 and a gate of the MOS transistor 222. A source of the MOS transistor 220 is connected to a power supply line Vdd, and a drain of the MOS transistor 220 is connected to a drain of the MOS transistor 221 and a gate of a MOS transistor 225 of the output unit 170. A gate of the MOS transistor 221 is connected to the signal line ON, and a source of the MOS transistor 221 is grounded. A source of the MOS transistor 222 is connected to a power supply line Vdd, and a drain of the MOS transistor 222 is connected to a drain of the MOS transistor 223 and a gate of a MOS transistor 227 of the output unit 170. A gate of the MOS transistor 223 is connected to the signal line OFF, and a source of the MOS transistor 223 is grounded.

The circuit including the MOS transistors 220 and 221 constitute a comparison circuit. An output of the comparison circuit varies depending on a magnitude relationship between a sink-side drain current of the MOS transistor 221 and a source-side drain current of the MOS transistor 220. When the output voltage of the differentiation circuit 150 is lower than a threshold based on the voltage of the on-event detection signal, specifically, a voltage obtained by subtracting the threshold voltage from the power supply voltage Vdd, a source current of the MOS transistor 220 is smaller than a sink current of the MOS transistor 221. Therefore, the output voltage is at an L level. On the other hand, when the output voltage of the differentiation circuit 150 becomes higher than the threshold voltage (the voltage obtained by subtracting the threshold voltage from the power supply voltage Vdd), the sink current of the MOS transistor 221 becomes smaller than the source current of the MOS transistor 220. Therefore, the output voltage shifts to an H level. In this manner, the comparison circuit including the MOS transistors 220 and 221 compares the output voltage of the differentiation circuit 150 with the threshold voltage of the on-event detection signal, and detects an on-event that is a change in a direction in which the luminance of the incident light increases. When the on-event detection signal is a voltage higher than the threshold voltage, e.g. a power supply voltage of the power supply line Vdd, the output of the comparator is always at the L level. That is, an on-event can be detected by applying a threshold voltage as an on-event detection signal.

The circuit including the MOS transistors 222 and 223 also constitute a comparison circuit. When the output voltage of the differentiation circuit 150 is lower than a threshold based on the voltage of the off-event detection signal, specifically, a voltage obtained by subtracting the threshold voltage from the power supply voltage Vdd, the output voltage is at the L level. On the other hand, when the output voltage of the differentiation circuit 150 becomes higher than the threshold voltage (the voltage obtained by subtracting the threshold voltage from the power supply voltage Vdd), the output voltage shifts to the H level. By setting the threshold of the off-event detection signal to a voltage lower than the threshold of the on-event detection signal, the comparison circuit including the MOS transistors 222 and 223 detects an off-event that is a change in a direction in which the luminance of the incident light decreases. When the off-event detection signal is a voltage lower than the threshold voltage, e.g., a ground potential, the output of the comparator is always at the H level. That is, an off-event can be detected by applying a threshold voltage as an off-event detection signal.

### <Configuration of Output Unit>

The output unit 170 includes MOS transistors 224 to 227. As the MOS transistors 224 to 227, n-channel MOS transistors can be used. A drain of the MOS transistor 224 is connected to one of the vertical signal lines 24, and a drain of the MOS transistor 226 is connected to the other one of the vertical signal lines 24. Gates of the MOS transistors 224 and 226 are commonly connected to the signal line OUT. A source of the MOS transistor 224 is connected to a drain of the MOS transistor 225, and a source of the MOS transistor 225 is grounded. The source of the MOS transistor 226 is connected to a drain of the MOS transistor 227, and a source of the MOS transistor 227 is grounded.

When an event read signal is input to the signal line OUT, the MOS transistors 224 and 226 become conductive. As a result, drain voltages of the MOS transistors 225 and 227 are output to the vertical signal lines 24. Since the on-event detection signal and the off-event detection signal of the luminance change detection unit 160 are applied to the gates of the MOS transistors 225 and 227, event signals including an on-event signal and an off-event signal are output to the vertical signal lines 24.

In this manner, a gradation signal and an event signal are generated in the gradation signal generation unit 110 and the event signal generation unit 120, respectively. When generating a gradation signal, the vertical drive circuit 33 outputs a selection signal, a reset signal, and a transfer signal to pixels 12 in a row for generating a gradation signal. On the other hand, when generating an event signal, the vertical drive circuit 33 sequentially outputs an on-event detection signal, an off-event detection signal, and an AZ control signal to all the pixels 12 of the pixel array unit 13. Thereafter, output signals are sequentially output for all the rows of the pixel array unit 13 to output (read) event signals.

### <Configuration of Cross-Section of Pixel>

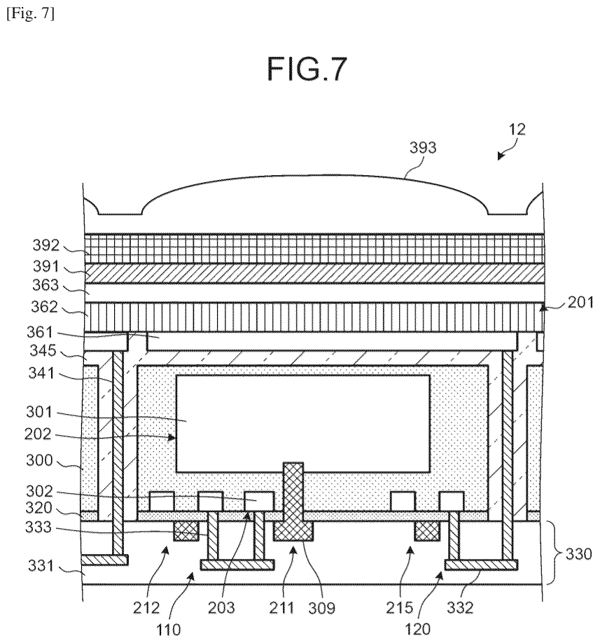

FIG. 7 is a cross-sectional view illustrating an example of a configuration of a pixel according to the first embodiment of the present disclosure. FIG. 7 is a cross-sectional view illustrating an example of a configuration of the pixel 12. The pixel 12 of FIG. 7 includes a semiconductor substrate 300, a through electrode 341, a wiring region 330, an insulating film 345, a first photoelectric conversion unit 201, a sealing film 391, a color filter 392, and an on-chip lens 393.

The semiconductor substrate 300 is a semiconductor substrate in which elements such as the second photoelectric conversion unit 202 are disposed. The second photoelectric conversion unit 202, the MOS transistors 211 and 212 included in the gradation signal generation unit 110, and the charge holding unit 203 are illustrated in the semiconductor substrate 300 of FIG. 7. In addition, the MOS transistor 215 included in the event signal generation unit 120 is further illustrated in the semiconductor substrate 300 of FIG. 7.

The semiconductor substrate 300 can be made of, for example, silicon (Si). The second photoelectric conversion unit 202, etc. are arranged in a well region formed in the semiconductor substrate 300. For convenience, it is assumed that the semiconductor substrate 300 of FIG. 7 includes a p-type well region. An element can be formed by arranging an n-type or p-type semiconductor region in the p-type well region.

A rectangle illustrated in the semiconductor substrate 300 of FIG. 7 represents an n-type semiconductor region. The second photoelectric conversion unit 202 is constituted by an n-type semiconductor region 301. Specifically, a photodiode constituted by a p-n junction formed at an interface between the n-type semiconductor region 301 and a surrounding p-type well region corresponds to the second photoelectric conversion unit 202.

The charge holding unit 203 is constituted by an n-type semiconductor region 302. The semiconductor region 302 constitutes the above-described FD.

The MOS transistor 211 is constituted by the semiconductor regions 301 and 302 and a gate electrode 309. The n-type semiconductor regions 301 and 302 correspond to the source region and the drain region of the MOS transistor. The gate electrode 309 is disposed on the front surface side of the semiconductor substrate 300 and includes a columnar portion having a depth reaching the n-type semiconductor region 301. A gate insulating film (not illustrated) is disposed between the gate electrode 309 and the semiconductor substrate 300. When a drive voltage is applied to the gate electrode 309, a channel is formed in a well region adjacent to the gate electrode 309, such that the n-type semiconductor regions 301 and 302 are brought into a conductive state. That is, conduction is established between the second photoelectric conversion unit 202 and the charge holding unit 203, and a charge of the second photoelectric conversion unit 202 is transferred to the charge holding unit 203.

An insulating film 320 is disposed on the front surface side of the semiconductor substrate 300. The insulating film 320 is a film that insulates the front surface side of the semiconductor substrate 300. The insulating film 320 can be made of silicon oxide (SiO₂) or silicon nitride (SIN).

The through electrode 341 is an electrode shaped to penetrate the semiconductor substrate 300. The through electrode 341 connects an element disposed on the back surface side of the semiconductor substrate 300 and an element disposed on the front surface side of the semiconductor substrate 300. The through electrode 341 of FIG. 7 transmits a signal of the first photoelectric conversion unit 201 to the event signal generation unit 120 arranged on the semiconductor substrate 300. As described above, the through electrode 341 can be made of, for example, W.

The wiring region 330 is a region disposed on the front surface side of the semiconductor substrate 300 to arrange wiring and the like for elements. The wiring region 330 includes an insulating layer 331 and wiring 332. The insulating layer 331 insulates the wiring 332 and the like. The insulating layer 331 can be made of, for example, SiO₂. The wiring 332 is a conductor that transmits a signal or the like of an element. The wiring 332 can be made of a metal such as W or copper (Cu). Note that the wiring 332 and the semiconductor region can be connected to each other by a contact plug 333. The contact plug 333 is made of a columnar metal. The through electrode 341 is connected to the wiring 332 of FIG. 7. Note that the semiconductor substrate 300 constitutes the semiconductor substrate 11 of FIG. 1.

The insulating film 345 insulates the semiconductor substrate 300 and the first photoelectric conversion unit 201 from each other. The insulating film 345 can be made of, for example, SiO₂.

The first photoelectric conversion unit 201 is an element disposed adjacent to the semiconductor substrate 300 to perform photoelectric conversion of incident light. The first photoelectric conversion unit 201 of FIG. 7 is adjacent to the semiconductor substrate 300 via the insulating film 345. The first photoelectric conversion unit 201 includes a first electrode 361, a photoelectric conversion film 362, and a second electrode 363.

The photoelectric conversion film 362 is constituted by, for example, an organic photoelectric conversion film, and is a film that generates a charge corresponding to incident light. The photoelectric conversion film 362 can be made of, for example, an organic photoelectric conversion material including a rhodamine dye, a merocyanine dye, quinacridone, a phthalocyanine dye, a coumarin dye, tris-8-hydroxyquinoline A1, or the like. The second electrode 363 is a transparent electrode disposed adjacent to the photoelectric conversion film 362. The second electrode 363 can be made of, for example, indium-tin oxide (ITO). The first electrode 361 is an electrode that reads out the charge generated by the photoelectric conversion film 362.

The second electrode 363 is grounded by wiring that is not illustrated. The first electrode 361 is connected to the event signal generation unit 120 via the through electrode 341.

The sealing film 391 seals the first photoelectric conversion unit 201. The color filter 392 is an optical filter that transmits light having a predetermined wavelength out of the incident light. The color filter 392 of FIG. 7 transmits infrared light and one of red light, green light, and blue light. The on-chip lens 393 is a lens that condenses incident light on the second photoelectric conversion unit 202.

As illustrated in FIG. 7, the first photoelectric conversion unit 201 and the second photoelectric conversion unit 202, which are stacked, are arranged in the pixel 12. As described above, the first photoelectric conversion unit 201 performs photoelectric conversion of visible light. As the color filter 392, a color filter that transmits one of red light, green light, and blue light in addition to infrared light is arranged. In this case, the color filter 392 corresponding to one of infrared light+red light, infrared light+green light, and infrared light+blue light is arranged in the pixel 12. The first photoelectric conversion unit 201 performs photoelectric conversion of infrared light transmitted by each color filter 392 arranged in the pixel 12. On the other hand, the second photoelectric conversion unit 202 performs photoelectric conversion of visible light transmitted through the first photoelectric conversion unit 201 and the color filter 392.

In this manner, the light detecting device 1 according to the first embodiment of the present disclosure generates a gradation signal and an event signal in the pixel 12. As a result, a movement of a subject can be detected at a high speed.

### 2. Second Embodiment

In the light detecting device 1 according to the first embodiment described above, the gradation signal generation unit 110 and the event signal generation unit 120 are arranged in the pixel 12. On the other hand, a light detecting device 1 according to the second embodiment of the present disclosure is different from the light detecting device 1 according to the first embodiment disclosure described above in that the gradation signal generation unit 110 is omitted.

### <Configuration of Pixel>

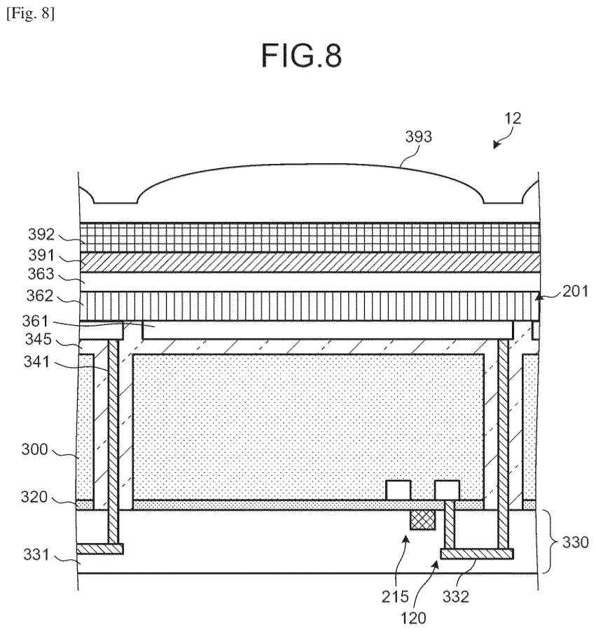

FIG. 8 is a cross-sectional view illustrating an example of a configuration of a pixel according to the second embodiment of the present disclosure. Similarly to FIG. 7, FIG. 8 is a cross-sectional view illustrating an example of a configuration of a pixel 12. The pixel 12 of FIG. 8 is different from the pixel 12 of FIG. 7 in that the second photoelectric conversion unit 202 and the gradation signal generation unit 110 are omitted.

Since the other configurations of the light detecting device 1 are similar to those of the light detecting device 1 according to the first embodiment of the present disclosure, the description thereof will be omitted.

In this manner, the light detecting device 1 according to the second embodiment of the present disclosure generates an event signal in the pixel 12. As a result, a movement of a subject can be detected at a high speed.

### 3. Third Embodiment

In the light detecting device 1 according to the second embodiment described above, the elements of the event signal generation unit 120 are arranged in the semiconductor substrate 300. On the other hand, a light detecting device 1 according to the third embodiment of the present disclosure is different from the light detecting device 1 according to the first embodiment described above in that some of the elements of the event signal generation unit 120 are disposed adjacent to the first photoelectric conversion unit 201.

### <Configuration of Pixel>

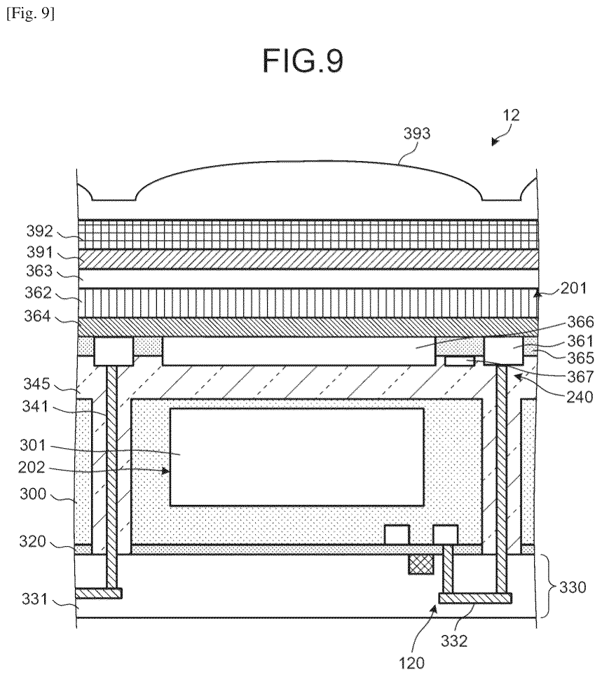

FIG. 9 is a cross-sectional view illustrating an example of a configuration of a pixel according to the third embodiment of the present disclosure. Similarly to FIG. 8, FIG. 9 is a cross-sectional view illustrating an example of a configuration of a pixel 12. The pixel 12 of FIG. 9 is different from the pixel 12 of FIG. 8 in that an element 240 is arranged instead of the MOS transistor 215. The element 240 is an element constituted by a semiconductor layer disposed adjacent to the first photoelectric conversion unit 201.

In the pixel 12 of FIG. 9, a transparent semiconductor layer 364, an insulating film 365, a third electrode 366, and an electrode 367 are further disposed under the photoelectric conversion film 362. The element 240 of FIG. 9 is constituted by the transparent semiconductor layer 364, the insulating film 365, the third electrode 366, and the electrode 367.

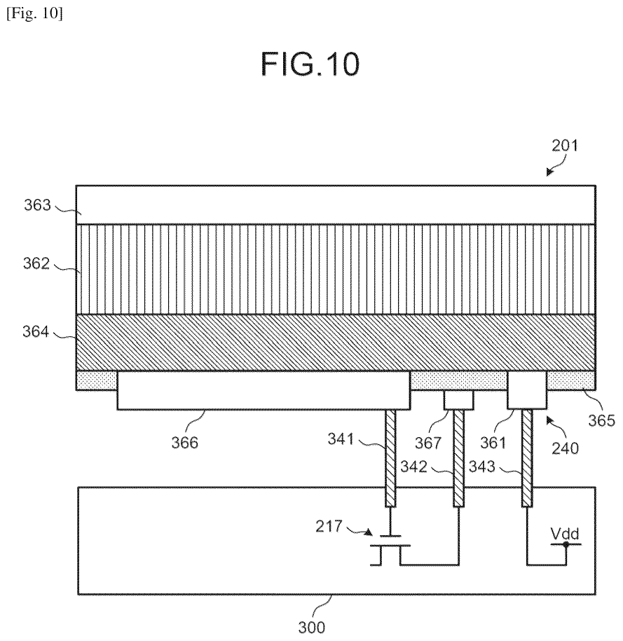

The transparent semiconductor layer 364 constitutes a path for transmitting a charge generated by the photoelectric conversion film 362. The transparent semiconductor layer 364 can be constituted by, for example, an oxide semiconductor film made of indium-gallium-zinc oxide (IGZO) or the like. The insulating film 365 is a film that insulates the transparent semiconductor layer 364 and the electrode 367 from each other. The insulating film 365 can be made of, for example, SiO₂. The electrode 367 can be made of, for example, ITO. The configuration of the element 240 will be described with reference to FIG. 10.

FIG. 10 is a diagram illustrating an example of a configuration of an element according to the third embodiment of the present disclosure. FIG. 10 is a cross-sectional view illustrating an example of a configuration of the element 240. The third electrode 366 is disposed under the transparent semiconductor layer 364. The first electrode 361 of FIG. 10 is disposed adjacent to an end of the transparent semiconductor layer 364. The electrode 367 is disposed in a region between the third electrode 366 and the first electrode 361. The electrode 367 is disposed adjacent to the transparent semiconductor layer 364 via the insulating film 365. The charge generated by the photoelectric conversion film 362 moves in the photoelectric conversion film 362 in a longitudinal direction (a normal direction of the front surface of the semiconductor substrate 300) to reach the transparent semiconductor layer 364, and moves in a transverse direction in the transparent semiconductor layer 364 to be transmitted to the first electrode 361. A voltage for adjusting the movement of the charge in the transparent semiconductor layer 364 is applied to the electrode 367. In addition, an input voltage of the event signal generation unit 120 is read from the third electrode 366.

As illustrated in FIG. 10, the third electrode 366 is connected to the gate of the MOS transistor 217 via the through electrode 341. The electrode 367 is connected to the drain terminal of the MOS transistor 217 via a through electrode 342. The first electrode 361 is connected to the power supply line Vdd via a through electrode 343. In this manner, some elements of the event signal generation unit 120 can be formed in the vicinity of the photoelectric conversion film 362 constituting the first photoelectric conversion unit 201. Note that the transparent semiconductor layer 364 is an example of a “semiconductor layer” in the present disclosure.

Since the other configurations of the light detecting device 1 are similar to those of the light detecting device 1 according to the second embodiment of the present disclosure, the description thereof will be omitted.

As described above, in the light detecting device 1 according to the third embodiment of the present disclosure, some elements of the event signal generation unit 120 can be formed in the vicinity of the photoelectric conversion film 362. As a result, the number of elements of the semiconductor substrate 300 can be reduced.

### 4. Fourth Embodiment

In the light detecting device 1 according to the first embodiment described above, the second photoelectric conversion unit 202 and the first photoelectric conversion unit 201 are used. On the other hand, a light detecting device 1 according to the fourth embodiment of the present disclosure is different from the light detecting device 1 according to the first embodiment described above in that a gradation signal generation unit 110 and an event signal generation unit 120 share a photoelectric conversion unit.

### <Configurations of Gradation Signal Generation Unit and Event Signal Generation Unit>

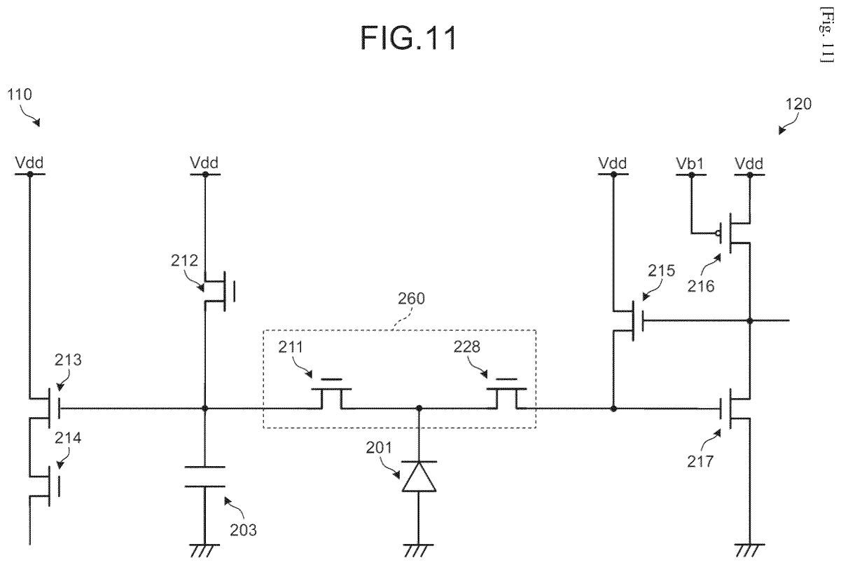

FIG. 11 is a circuit diagram illustrating examples of configurations of a gradation signal generation unit and an event signal generation unit according to the fourth embodiment of the present disclosure. FIG. 11 is a circuit diagram illustrating examples of configurations of the gradation signal generation unit 110 and the event signal generation unit 120. For convenience, illustration of some signal lines is omitted in FIG. 11.

A first photoelectric conversion unit 201 is commonly connected to the gradation signal generation unit 110 and the event signal generation unit 120 in FIG. 11. Furthermore, a MOS transistor 228 is further arranged in the circuit of FIG. 11. The MOS transistor 228 is an element connected to the first photoelectric conversion unit 201. As the MOS transistor 228, an n-channel MOS transistor can be applied. The cathode of the first photoelectric conversion unit 201 is connected to the source of the MOS transistor 211 and a source of the MOS transistor 228. A drain of the MOS transistor 228 is connected to the source of the MOS transistor 215 and the gate of the MOS transistor 217. The other wirings are similar to those of the circuits of FIGS. 3 and 5, and thus the description thereof is omitted.

The MOS transistors 211 and 228 of FIG. 11 can be disposed in the semiconductor substrate 300. Note that the circuit including the MOS transistor 211 and the MOS transistor 228 is a circuit that connects the first photoelectric conversion unit 201 to the gradation signal generation unit 110 and the event signal generation unit 120. This circuit is referred to as a first connection circuit 260.

### <Configuration of Pixel>

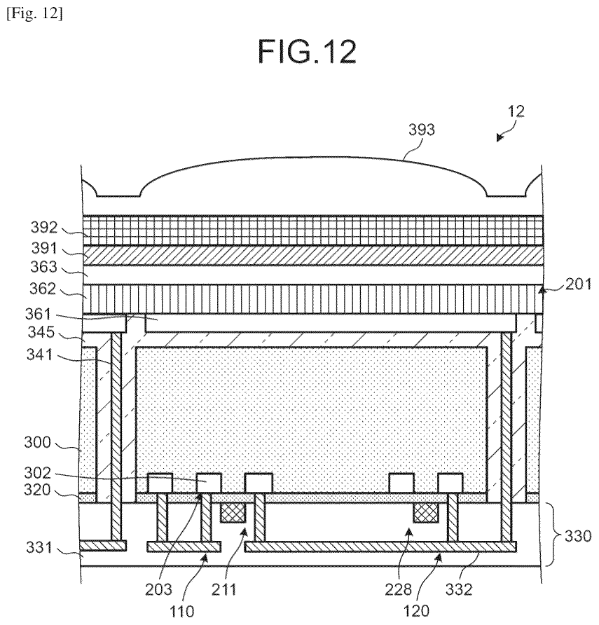

FIG. 12 is a cross-sectional view illustrating an example of a configuration of a pixel according to the fourth embodiment of the present disclosure. Similarly to FIG. 7, FIG. 12 is a cross-sectional view illustrating an example of a configuration of a pixel 12. The pixel 12 of FIG. 12 is different from the pixel 12 of FIG. 7 in that the second photoelectric conversion unit 202 is omitted.

The MOS transistor 211 of the gradation signal generation unit 110 in FIG. 12 is constituted by a flat-plate gate MOS transistor. Further, a MOS transistor 228 is disposed in the semiconductor substrate 300 of FIG. 12. The MOS transistor 211 and the MOS transistor 228 are connected to the first photoelectric conversion unit 201 via the through electrode 341 and wiring 322.

### <Other Configurations of Gradation Signal Generation Unit and Event Signal Generation Unit>

The gradation signal generation unit 110 and the event signal generation unit 120 in FIG. 11 use the first connection circuit 260 including the MOS transistors 211 and 228. On the other hand, the first connection circuit 260 can also be configured using an element (an element 241 and an element 242 to be described below) constituted by a semiconductor layer disposed adjacent to the first photoelectric conversion unit 201.

### <Configuration of Element>

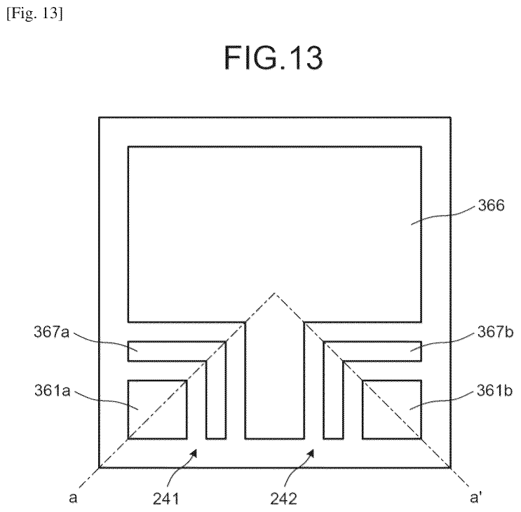

FIG. 13 is a plan view illustrating an example of a configuration of an element according to the fourth embodiment of the present disclosure. FIG. 13 is a plan view illustrating examples of configurations of elements 241 and 242. The third electrode 366 of FIG. 13 has a T-shape in the plan view. A first electrode 361a and a first electrode 361b are arranged on lower left side and the lower right side of the third electrode 366 of FIG. 13, respectively. Further, an electrode 367a is disposed between the third electrode 366 and the first electrode 361a, and an electrode 367b is disposed between the third electrode 366 and the first electrode 361b. The first electrode 361a, the electrode 367a, and the third electrode 366 are included in the element 241. In addition, the first electrode 361b, the electrode 367b, and the third electrode 366 are included in the element 242.

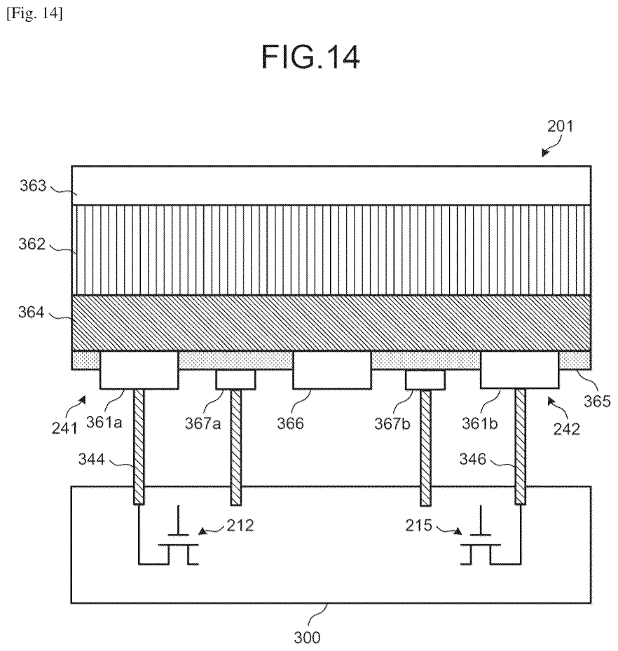

FIG. 14 is a diagram illustrating an example of a configuration of an element according to the fourth embodiment of the present disclosure. FIG. 14 is a cross-sectional view illustrating examples of configurations of elements 241 and 242. Also, FIG. 14 is a diagram schematically illustrating a shape of a cross section taken along line a-a′ in FIG. 13. As illustrated in FIG. 14, the first electrode 361a of the element 241 is connected to a source terminal of the MOS transistor 212 via a through electrode 344. In addition, the first electrode 361b of the element 242 is connected to a source terminal of the MOS transistor 215 via a through electrode 346.

### <Other Circuit Configurations of Gradation Signal Generation Unit and Event Signal Generation Unit>

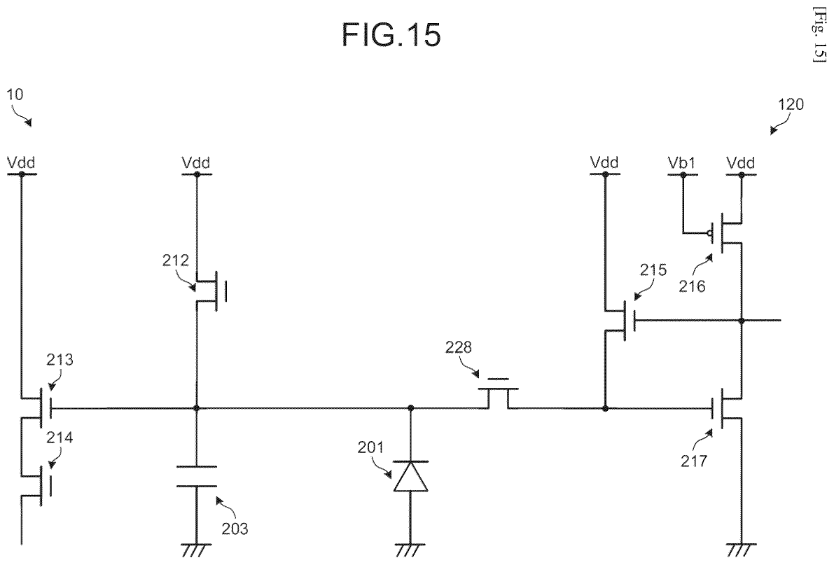

FIG. 15 is a circuit diagram illustrating examples of other configurations of a gradation signal generation unit and an event signal generation unit according to the fourth embodiment of the present disclosure. Similarly to FIG. 11, FIG. 15 is a circuit diagram illustrating examples of configurations of the gradation signal generation unit 110 and the event signal generation unit 120. The gradation signal generation unit 110 and the event signal generation unit 120 of FIG. 15 are different from the gradation signal generation unit 110 and the event signal generation unit 120 of FIG. 11 in that the MOS transistor 211 of the gradation signal generation unit 110 is omitted. Note that the circuit including the gradation signal generation unit 110 and the event signal generation unit 120 in FIG. 15 can also be considered as a circuit in which the MOS transistor 211 of the first connection circuit 260 illustrated in FIG. 11 is omitted.

In the gradation signal generation unit 110 of FIG. 15, the cathode of the first photoelectric conversion unit 201 is directly connected to the MOS transistor 212 and the charge holding unit 203.

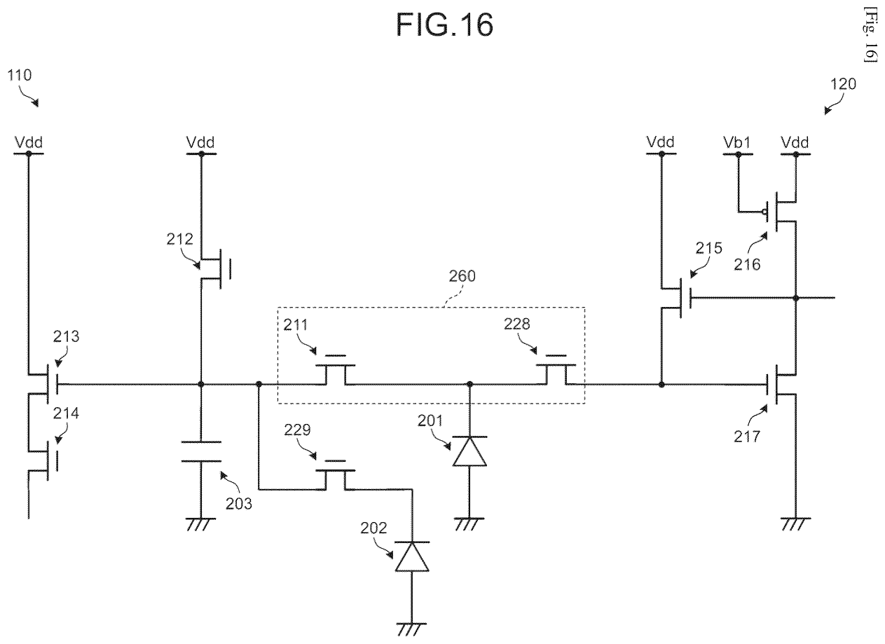

FIG. 16 is a circuit diagram illustrating examples of other configurations of a gradation signal generation unit and an event signal generation unit according to the fourth embodiment of the present disclosure. Similarly to FIG. 11, FIG. 16 is a circuit diagram illustrating examples of configurations of the gradation signal generation unit 110 and the event signal generation unit 120. The gradation signal generation unit 110 and the event signal generation unit 120 of FIG. 16 are different from the gradation signal generation unit 110 and the event signal generation unit 120 of FIG. 11 in that a second photoelectric conversion unit 202 and a MOS transistor 229 are further arranged. As the MOS transistor 229, an n-channel MOS transistor can be applied.

The anode of the second photoelectric conversion unit 202 is grounded, and the cathode of the second photoelectric conversion unit 202 is connected to a source of the MOS transistor 229. A drain of the MOS transistor 229 is connected to the drain of the MOS transistor 211.

The gradation signal generation unit 110 of FIG. 16 can generate a gradation signal on the basis of charges generated by the first photoelectric conversion unit 201 and the second photoelectric conversion unit 202. For example, in a case where an event signal is not generated in the event signal generation unit 120, the MOS transistor 228 is brought into a non-conductive state and the MOS transistors 211 and 229 are made conductive, such that the charges generated by the first photoelectric conversion unit 201 and the second photoelectric conversion unit 202 can be transferred to the charge holding unit 203. As a result, the sensitivity of the gradation signal generation unit 110 can be improved.

Since the other configurations of the light detecting device 1 are similar to those of the light detecting device 1 according to the first embodiment of the present disclosure, the description thereof will be omitted.

In this manner, in the light detecting device 1 according to the fourth embodiment of the present disclosure, the gradation signal generation unit 110 and the event signal generation unit 120 share the first photoelectric conversion unit 201. As a result, the configuration of the semiconductor substrate 300 can be simplified.

### 5. Fifth Embodiment

In the light detecting device 1 according to the first embodiment described above, the first photoelectric conversion unit 201 is connected to the event signal generation unit 120, and the second photoelectric conversion unit 202 is connected to the gradation signal generation unit 110. On the other hand, a light detecting device 1 according to the fifth embodiment of the present disclosure is different from the light detecting device 1 according to the first embodiment described above in that the first photoelectric conversion unit 201 is connected to the gradation signal generation unit 110 and the second photoelectric conversion unit 202 is connected to the event signal generation unit 120.

### <Circuit Configurations of Gradation Signal Generation Unit and Event Signal Generation Unit>

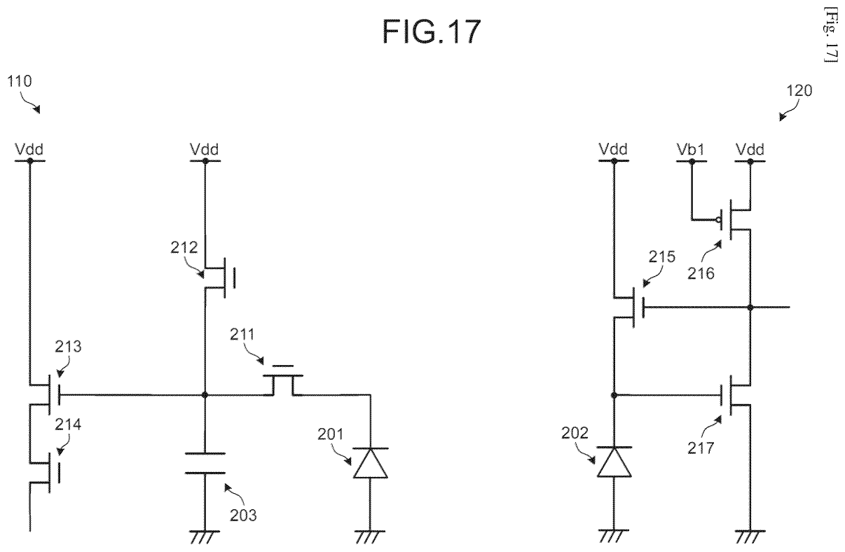

FIG. 17 is a circuit diagram illustrating examples of configurations of a gradation signal generation unit and an event signal generation unit according to the fifth embodiment of the present disclosure. Similarly to FIGS. 3 and 5, FIG. 17 is a circuit diagram illustrating examples of configurations of the gradation signal generation unit 110 and the event signal generation unit 120. The gradation signal generation unit 110 of FIG. 17 is different from the gradation signal generation unit 110 of FIG. 3 in that the first photoelectric conversion unit 201 is connected thereto instead of the second photoelectric conversion unit 202. In addition, the event signal generation unit 120 of FIG. 17 is different from the event signal generation unit 120 of FIG. 5 in that the second photoelectric conversion unit 202 is connected thereto instead of the first photoelectric conversion unit 201.

The cathode of the first photoelectric conversion unit 201 is connected to the source of the MOS transistor 211 of the gradation signal generation unit 110. The cathode of the second photoelectric conversion unit 202 is connected to the source of the MOS transistor 215 of the event signal generation unit 120.

### <Configuration of Pixel>

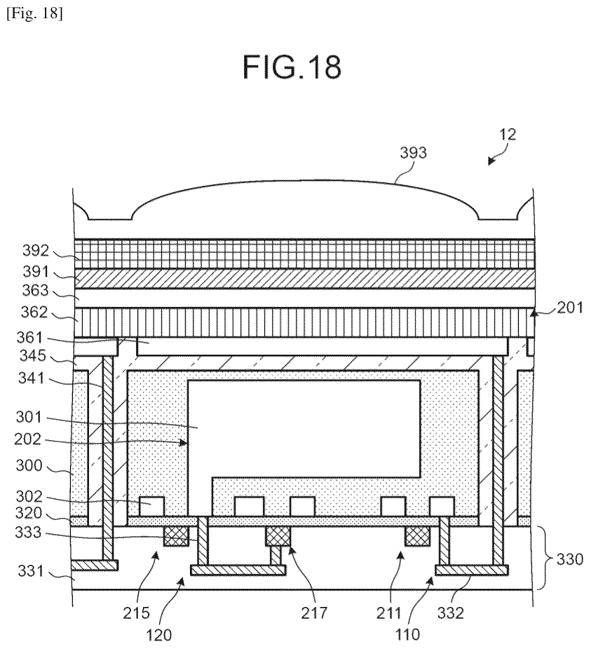

FIG. 18 is a cross-sectional view illustrating an example of a configuration of a pixel according to the fifth embodiment of the present disclosure. As illustrated in FIG. 18, the gradation signal generation unit 110 is connected to the first photoelectric conversion unit 201 via the through electrode 341. On the other hand, the event signal generation unit 120 is connected to the second photoelectric conversion unit 202. Note that the n-type semiconductor region 301 constituting the second photoelectric conversion unit 202 in FIG. 18 has a shape in which a part of the region is close to the front surface of the semiconductor substrate 300. This region corresponds to a source region of the MOS transistor 215, and is connected to the gate of the MOS transistor 217 via the contact plug 333 and the wiring 332.

### <Other Circuit Configurations of Gradation Signal Generation Unit and Event Signal Generation Unit>

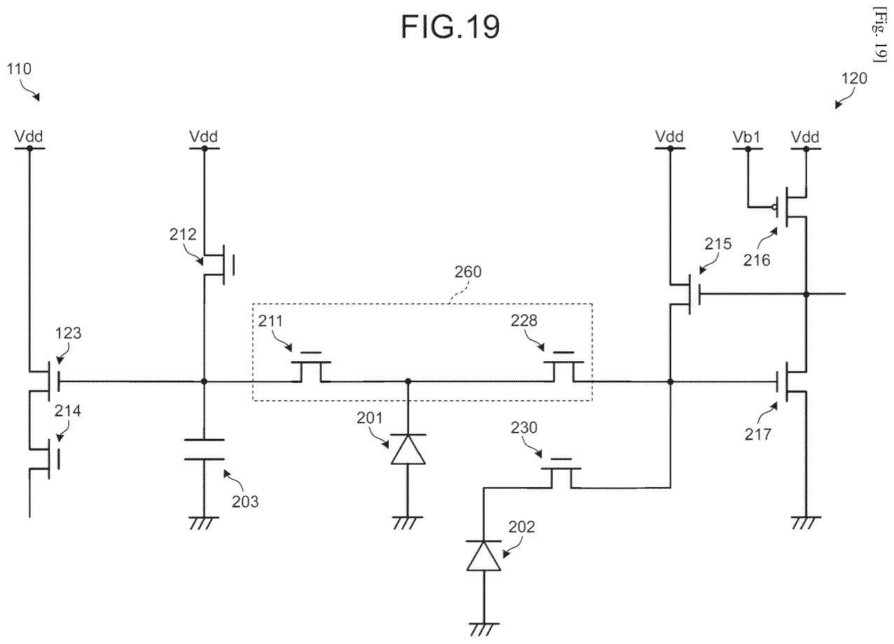

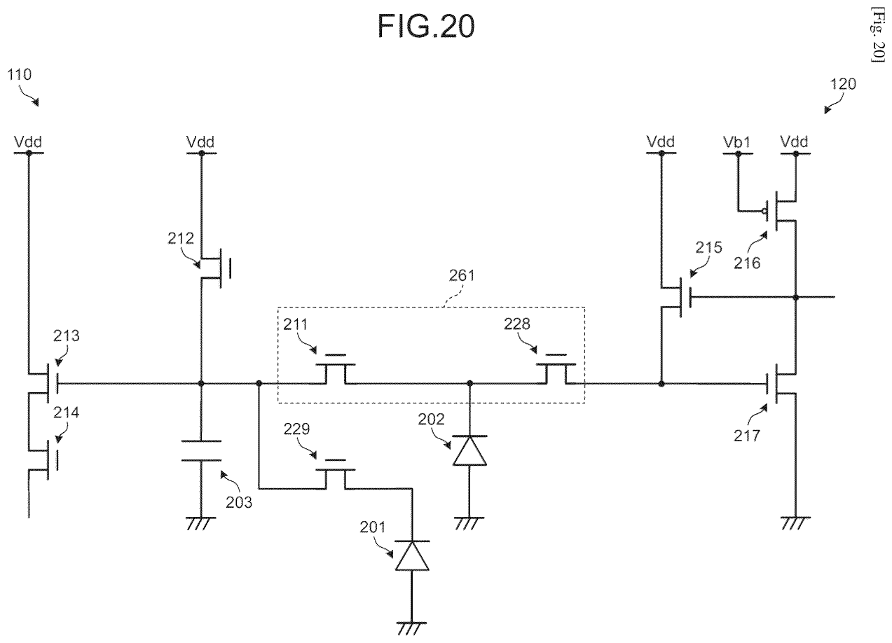

FIGS. 19 and 20 are circuit diagrams illustrating examples of other configurations of a gradation signal generation unit and an event signal generation unit according to the fifth embodiment of the present disclosure. FIGS. 19 and 20 are circuit diagrams illustrating examples of configurations of the gradation signal generation unit 110 and the event signal generation unit 120.

Similarly to FIG. 11, FIG. 19 illustrates an example of a circuit in which the first photoelectric conversion unit 201 is connected to the gradation signal generation unit 110 and the event signal generation unit 120 via a circuit including the MOS transistor 211 and the MOS transistor 228. The gradation signal generation unit 110 and the event signal generation unit 120 of FIG. 19 are different from the gradation signal generation unit 110 and the event signal generation unit 120 of FIG. 11 in that the second photoelectric conversion unit 202 is further connected to the event signal generation unit 120 via a MOS transistor 230.

FIG. 20 illustrates an example of a circuit in which the second photoelectric conversion unit 202 is connected to the gradation signal generation unit 110 and the event signal generation unit 120 via a circuit including the MOS transistor 211 and the MOS transistor 228. Furthermore, the first photoelectric conversion unit 201 is further connected to the gradation signal generation unit 110 via the MOS transistor 229.

Note that a circuit including the MOS transistor 211 and the MOS transistor 228 of FIG. 20 is a circuit that connects the second photoelectric conversion unit 202 to the gradation signal generation unit 110 and the event signal generation unit 120. This circuit is referred to as a second connection circuit 261.

Since the other configurations of the light detecting device 1 are similar to those of the light detecting device 1 according to the first embodiment of the present disclosure, the description thereof will be omitted.

In this manner, in the light detecting device 1 according to the fifth embodiment of the present disclosure, the first photoelectric conversion unit 201 constituted by the photoelectric conversion film 362 is connected to the gradation signal generation unit 110. In addition, the second photoelectric conversion unit 202 formed in the semiconductor substrate 300 is connected to the event signal generation unit 120 to generate an event signal.

### 6. Sixth Embodiment

A modification of the light detecting device 1 will be described.

### <Other Circuit Configurations of Gradation Signal Generation Unit and Event Signal Generation Unit>

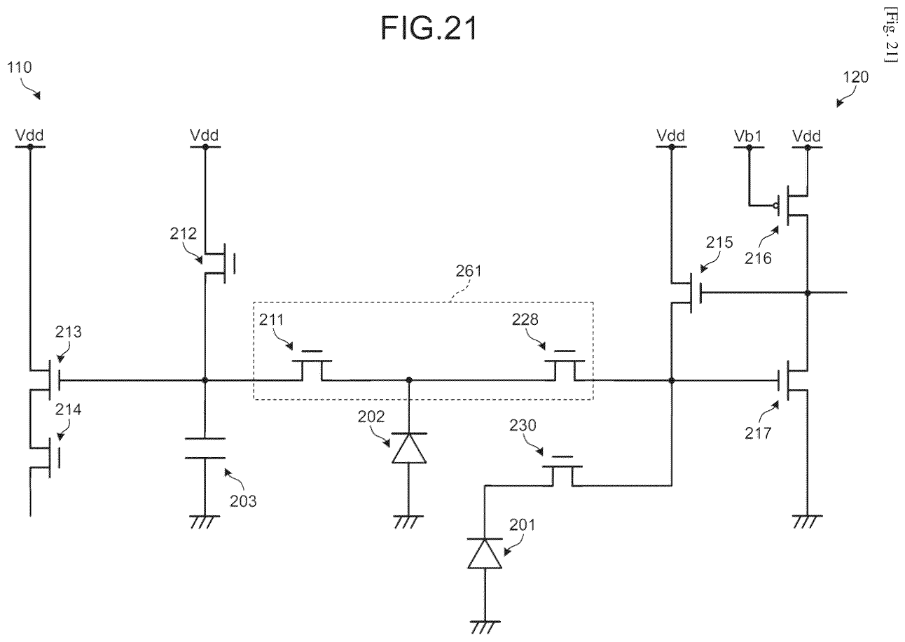

FIG. 21 is a circuit diagram illustrating examples of other configurations of a gradation signal generation unit and an event signal generation unit according to the modification of the embodiment of the present disclosure. Similarly to FIG. 20, FIG. 21 is a circuit diagram illustrating examples of configurations of the gradation signal generation unit 110 and the event signal generation unit 120. The gradation signal generation unit 110 and the event signal generation unit 120 of FIG. 21 are different from the gradation signal generation unit 110 and the event signal generation unit 120 of FIG. 20 in that the first photoelectric conversion unit 201 is further connected to the event signal generation unit 120 via a MOS transistor 230.

### <Configuration of Pixel>

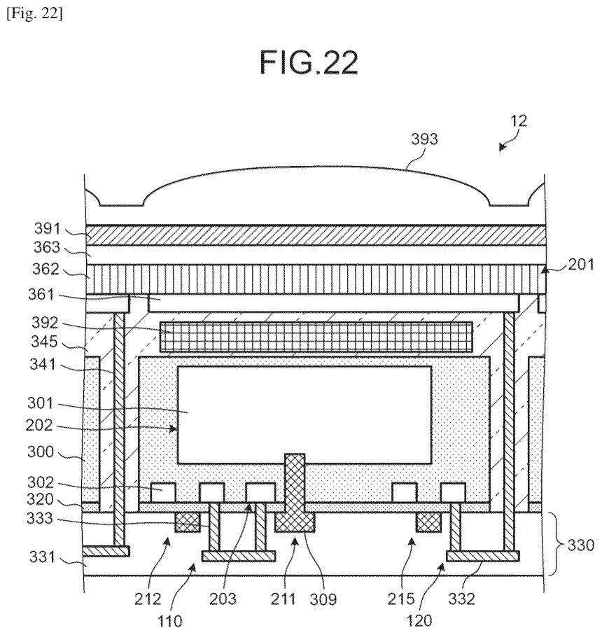

FIG. 22 is a cross-sectional view illustrating an example of a configuration of a pixel according to the modification of the embodiment of the present disclosure. Similarly to FIG. 7, FIG. 22 is a cross-sectional view illustrating an example of a configuration of a pixel 12. The pixel 12 of FIG. 22 is different from the pixel 12 in FIG. 7 in that a color filter 394 is arranged between the first electrode 361 disposed under the photoelectric conversion film 362 and the semiconductor substrate 300.

The first photoelectric conversion unit 201 of FIG. 22 can perform photoelectric conversion of infrared light, red light, green light, and blue light out of incident light. As a result, the sensitivity of the first photoelectric conversion unit 201 can be improved. Note that the first photoelectric conversion unit 201 can also perform photoelectric conversion of red light, green light, and blue light. The second photoelectric conversion unit 202 performs photoelectric conversion of visible light transmitted through the first photoelectric conversion unit 201 and the color filter 394.

Note that the pixel 12 of FIG. 22 may further include the color filter 392 described with reference to FIG. 7. In this case, by reducing the thickness of the organic photoelectric conversion film 362, some of incident light that is visible light transmitted through the color filter 392 is absorbed by the first photoelectric conversion unit 201. In addition, incident light that is visible light transmitted through the first photoelectric conversion unit 201 reaches the second photoelectric conversion unit 202.

### <Another Configuration of Pixel>

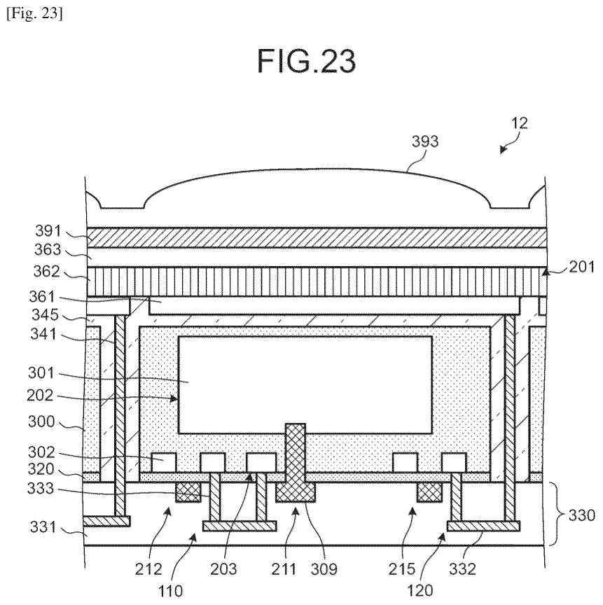

FIG. 23 is a cross-sectional view illustrating an example of another configuration of a pixel according to the modification of the embodiment of the present disclosure. Similarly to FIG. 7, FIG. 23 is a cross-sectional view illustrating an example of a configuration of a pixel 12. The pixel 12 of FIG. 23 is different from the pixel 12 of FIG. 7 in that the color filter 392 is omitted.

The first photoelectric conversion unit 201 of FIG. 23 can perform photoelectric conversion of infrared light, red light, green light, and blue light out of incident light. In addition, the second photoelectric conversion unit 202 of FIG. 23 can perform photoelectric conversion of infrared light. In this case, the gradation signal generation unit 110 generates a gradation signal based on the infrared light. The gradation signal based on the infrared light can be used as, for example, a distance measurement signal for measuring a distance to a subject.

### <Configuration of Photoelectric Conversion Unit>

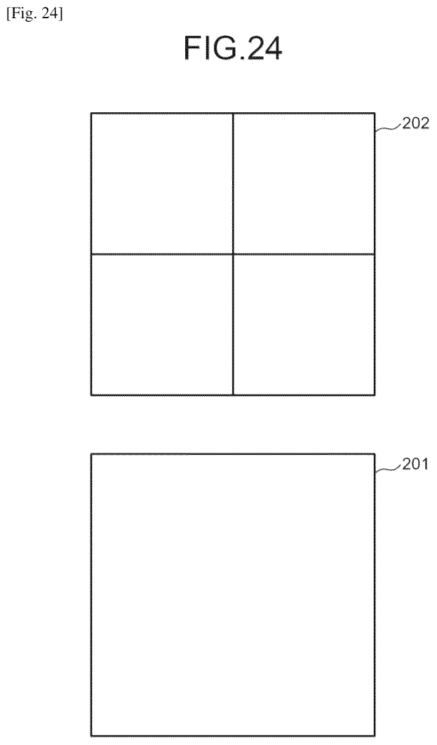

FIG. 24 is a diagram illustrating an example of a configuration of a photoelectric conversion unit according to a modification of the embodiment of the present disclosure. FIG. 24 is a diagram illustrating examples of configurations of the second photoelectric conversion unit 202 and the first photoelectric conversion unit 201. As illustrated in FIG. 24, the second photoelectric conversion unit 202 and the first photoelectric conversion unit 201 can be configured to have different sizes. FIG. 24 illustrates an example in which the first photoelectric conversion unit 201 has a size four times larger than a size of the second photoelectric conversion unit 202. In the example of FIG. 24, the sensitivity of the first photoelectric conversion unit 201 can be improved.

### 7. Seventh Embodiment

In the light detecting device 1 according to the first embodiment described above, the first photoelectric conversion unit 201 having an organic photoelectric conversion film is arranged for each pixel 12. On the other hand, a light detecting device 1 according to the seventh embodiment of the present disclosure is different from the light detecting device 1 according to the first embodiment described above in that a first photoelectric conversion unit 201 that absorbs visible light having a specific wavelength with respect to visible light included in incident light is arranged in a pixel 12.

### <Configuration of Pixel>

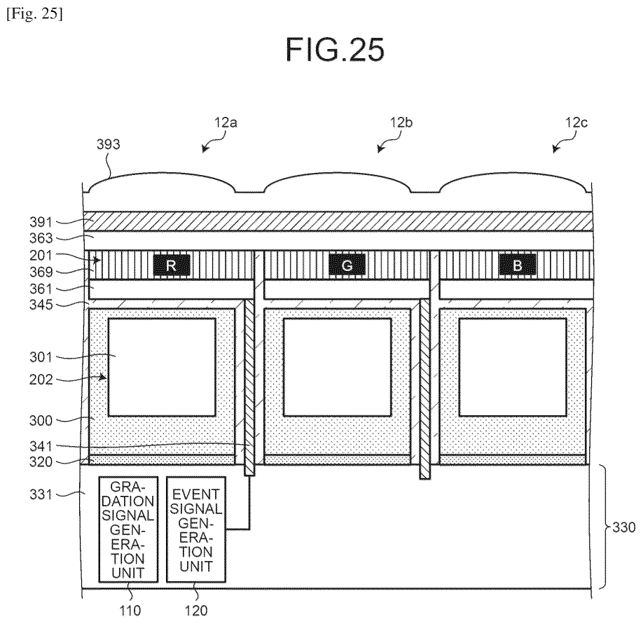

FIG. 25 is a cross-sectional view illustrating an example of a configuration of a pixel according to the seventh embodiment of the present disclosure. Similarly to FIG. 7, FIG. 25 is a cross-sectional view illustrating an example of a configuration of a pixel 12. The pixel 12 of FIG. 25 is different from the pixel 12 in FIG. 7 in that a photoelectric conversion film 369 is arranged instead of the photoelectric conversion film 362 constituting the first photoelectric conversion unit 201. Note that three pixels 12 (a pixel 12a, a pixel 12b, and a pixel 12c) are illustrated in FIG. 25. These pixels 12 are different from each other in the photoelectric conversion film 369 of the first photoelectric conversion unit 201. Note that a partial portion of the pixel 12 in FIG. 25 is omitted.

The configuration will be described using the pixel 12a as an example. The pixel 12a includes a first photoelectric conversion unit 201 having a photoelectric conversion film 369 and a second photoelectric conversion unit 202 arranged in the semiconductor substrate 300. The first photoelectric conversion unit 201 is connected to the event signal generation unit 120. In addition, the second photoelectric conversion unit 202 is connected to the gradation signal generation unit 110. The connection portion between the second photoelectric conversion unit 202 and the gradation signal generation unit 110 can have a configuration similar to that of FIG. 7. Note that, although not illustrated, event signal generation units 120 and gradation signal generation units 110 are also arranged in the pixels 12b and 12c, and are connected to respective first photoelectric conversion units 201 and respective second photoelectric conversion units 202.

The first photoelectric conversion unit 201 arranged in the pixel 12a or the like absorbs visible light having a specific wavelength with respect to visible light included in incident light, and performs photoelectric conversion. White letters attached to the photoelectric conversion film 369 of the pixel 12a or the like indicates the type of visible light absorbed by the first photoelectric conversion unit 201. In FIG. 25, “R” represents red light. “G” represents green light. “B” represents blue light. That is, the first photoelectric conversion unit 201 of the pixel 12a absorbs red light out of incident light to perform photoelectric conversion. Furthermore, the first photoelectric conversion unit 201 of the pixel 12b absorbs green light out of incident light to perform photoelectric conversion. Furthermore, the first photoelectric conversion unit 201 of the pixel 12c absorbs blue light out of incident light to perform photoelectric conversion. As described above, in the light detecting device 1 including the pixel 12a and the like of FIG. 25, the wavelength of the visible light absorbed by the first photoelectric conversion unit 201 is different for each pixel 12. The pixel 12a including the first photoelectric conversion unit 201 that absorbs red light, the pixel 12b including the first photoelectric conversion unit 201 that absorbs green light, and the pixel 12c including the first photoelectric conversion unit 201 that absorbs blue light can be arranged, for example, in a Bayer array in the pixel array unit 13.

The photoelectric conversion film 369 of the first photoelectric conversion unit 201 of the pixel 12a that absorbs red light can be made of, for example, an organic photoelectric conversion material including a phthalocyanine dye and a subphthalocyanine dye (subphthalocyanine derivative). Furthermore, the photoelectric conversion film 369 of the first photoelectric conversion unit 201 of the pixel 12b that absorbs green light can be made of, for example, an organic photoelectric conversion material including a rhodamine dye, a merocyanine dye, a quinacridone derivative, and a subphthalocyanine dye (subphthalocyanine derivative). Furthermore, the photoelectric conversion film 369 of the first photoelectric conversion unit 201 of the pixel 12c that absorbs blue light can be made of, for example, an organic photoelectric conversion material including a coumaric acid dye, tris-8-hydroxyquinoline aluminum (Alq3), and a melacyanine dye.

In the pixel 12 of FIG. 7, the first photoelectric conversion unit 201 absorbs infrared light to perform photoelectric conversion, and the second photoelectric conversion unit 202 performs photoelectric conversion of visible light. In this manner, in the pixel 12 in FIG. 7, the first photoelectric conversion unit 201 and the second photoelectric conversion unit 202 perform detection after dividing incident light into infrared light and visible light, decreasing convenience. Furthermore, in the pixel 12 in FIG. 22, the first photoelectric conversion unit 201 absorbs some of incident visible light, and the second photoelectric conversion unit 202 absorbs the remaining visible light to perform photoelectric conversion. That is, in the pixel 12 in FIG. 22, incident light having the same wavelength is divided and detected by the first photoelectric conversion unit 201 and the second photoelectric conversion unit 202, decreasing sensitivity. On the other hand, in the pixel 12a and the like of FIG. 25, the first photoelectric conversion units 201 and the second photoelectric conversion units 202 can be made to correspond to visible light having different wavelengths. Therefore, the first photoelectric conversion unit 201 and the second photoelectric conversion unit 202 can detect visible light with relatively high sensitivity. In addition, since there is no re-striction on the wavelength of the incident light detected by the first photoelectric conversion units 201 and the second photoelectric conversion units 202, it is possible to, for example, make a design according to the incident light having a wavelength at which quantum efficiency is high. Therefore, the degree of freedom in designing the pixel 12 can be improved.

### <Another Configuration of Pixel>

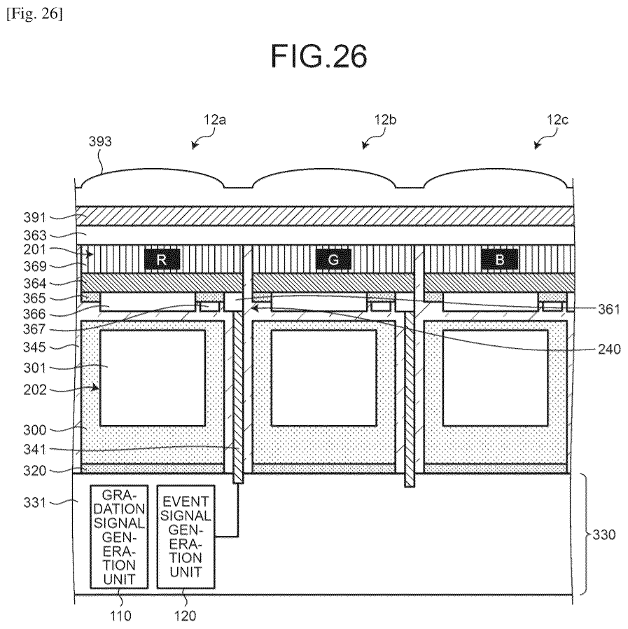

FIG. 26 is a cross-sectional view illustrating an example of another configuration of a pixel according to the seventh embodiment of the present disclosure. Similarly to FIG. 25, FIG. 26 is a cross-sectional view illustrating an example of a configuration of a pixel 12. FIG. 26 illustrates an example in which the pixel 12 (a pixel 12a, a pixel 12b, and a pixel 12c) further includes an element 240 described with reference to FIG. 9. As described above, the element 240 includes a transparent semiconductor layer 364, an insulating film 365, a third electrode 366, and an electrode 367.

### <Method of Manufacturing Light Detecting Device>

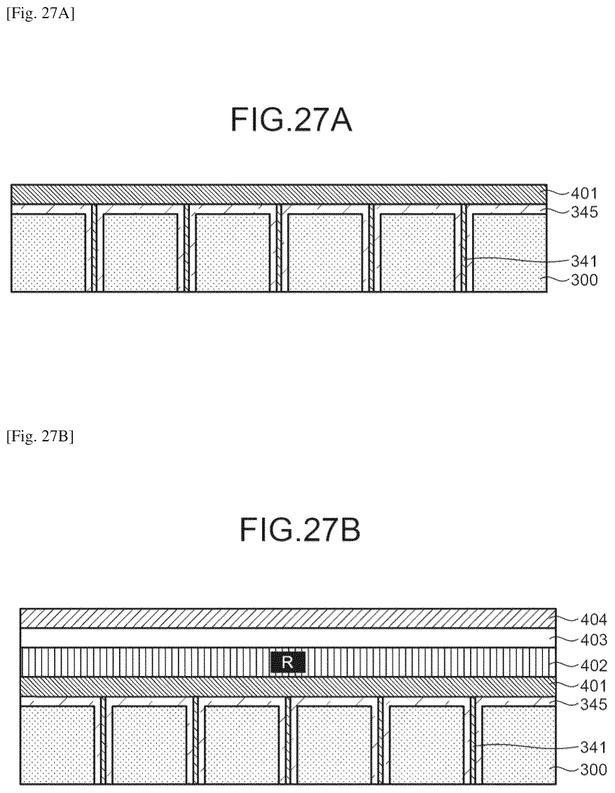

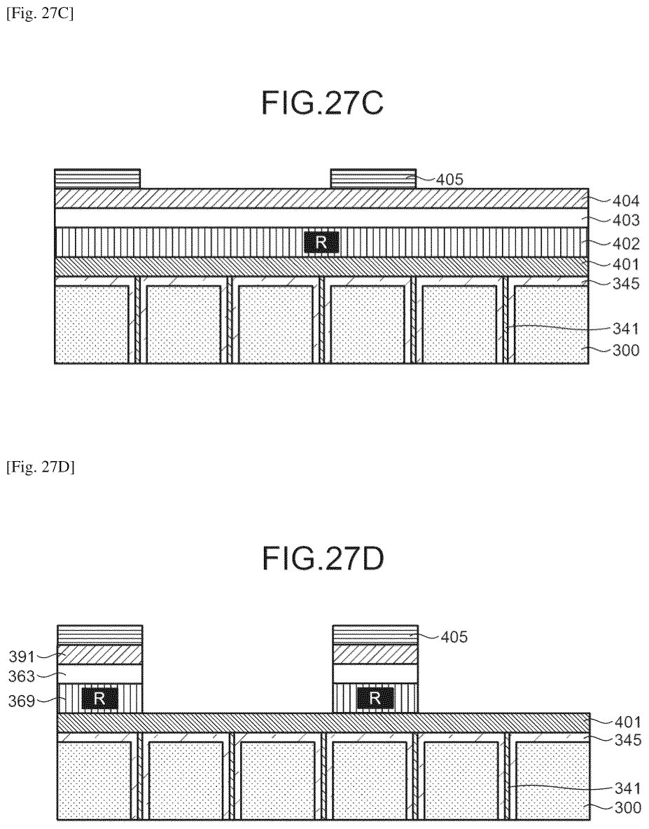

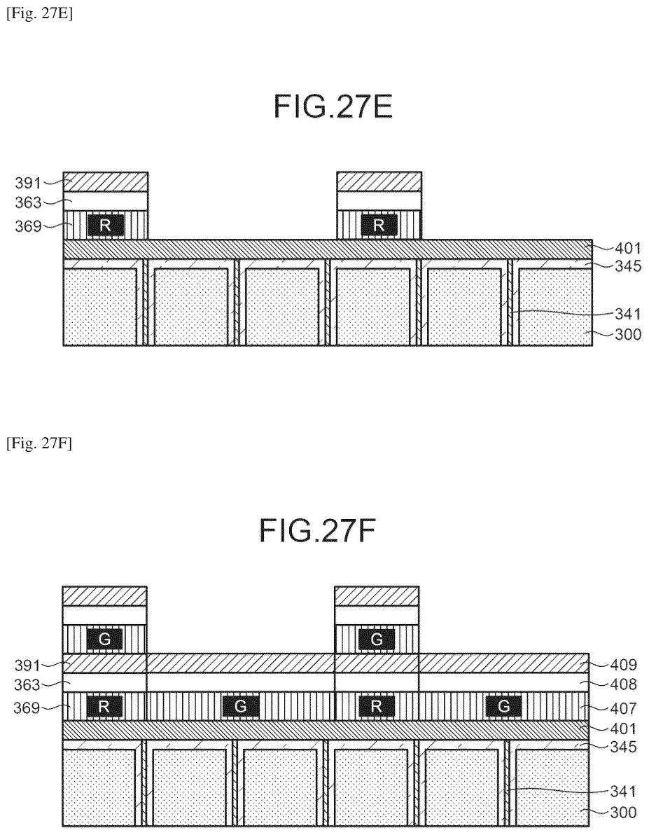

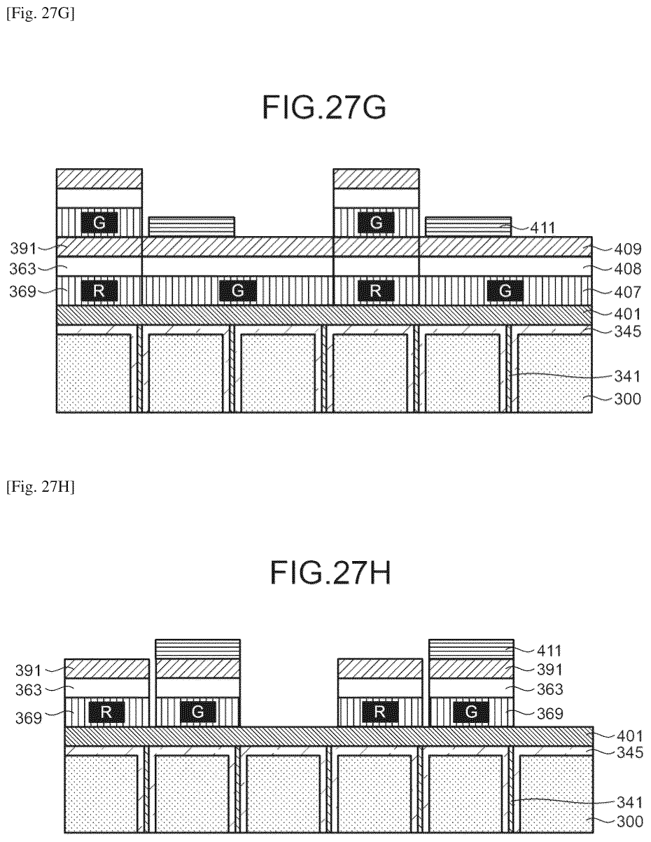

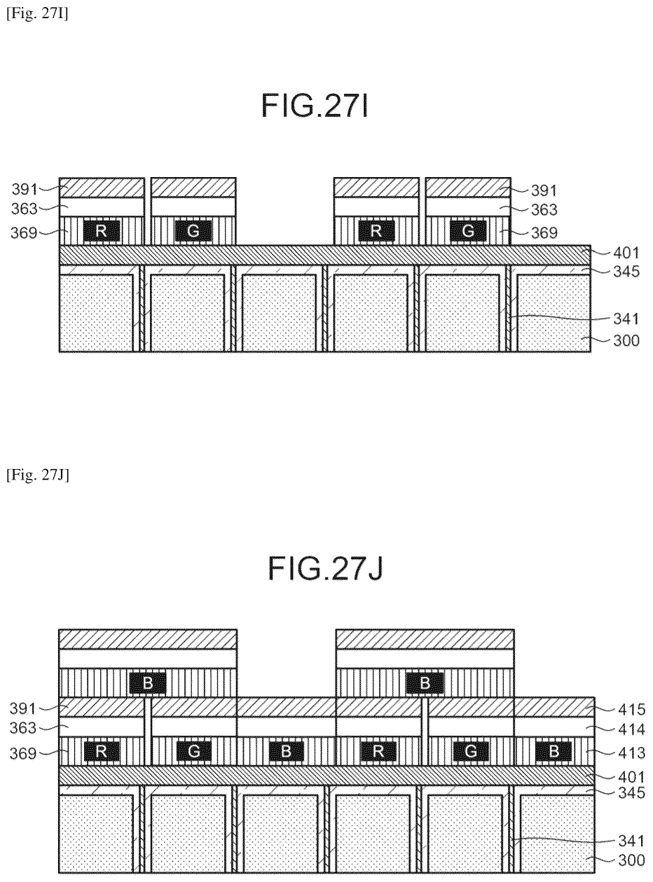

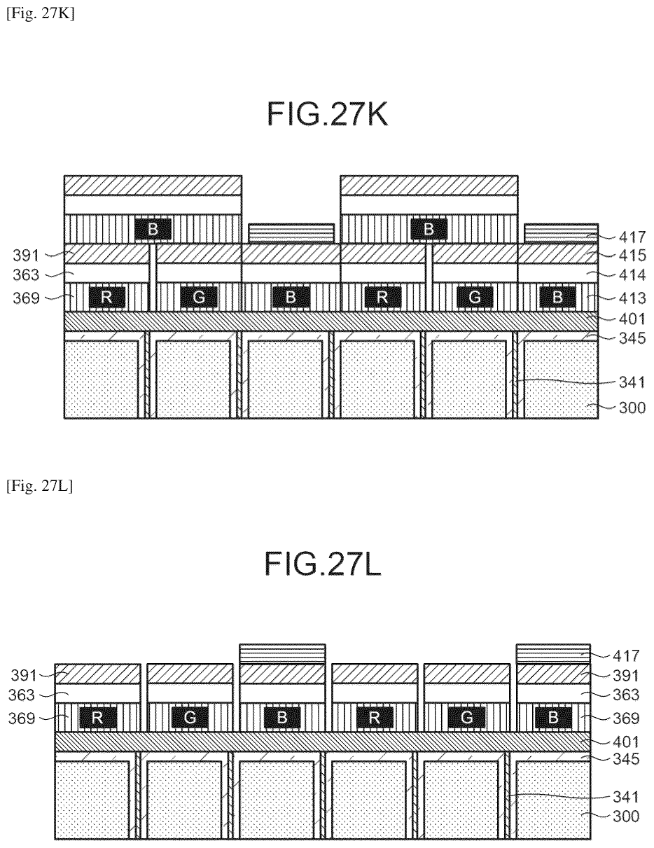

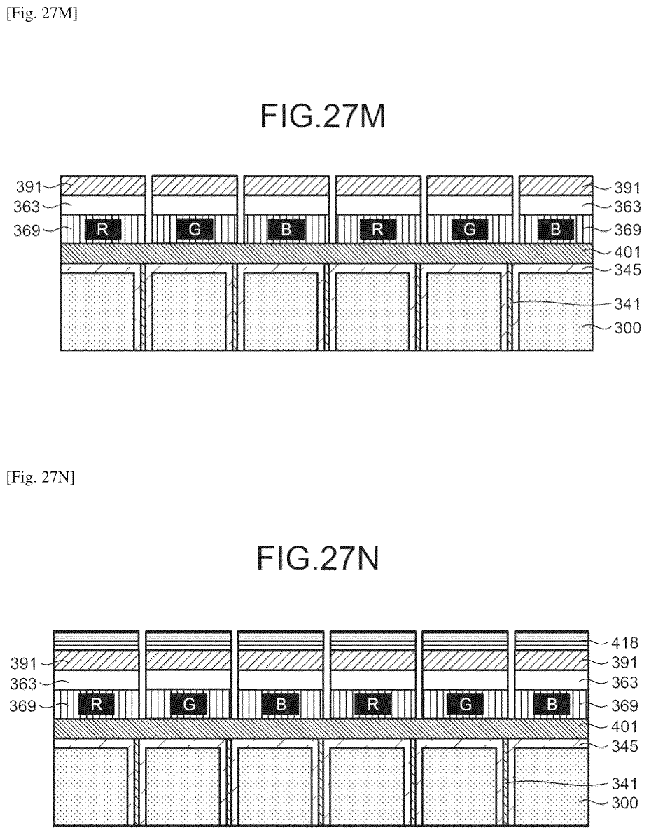

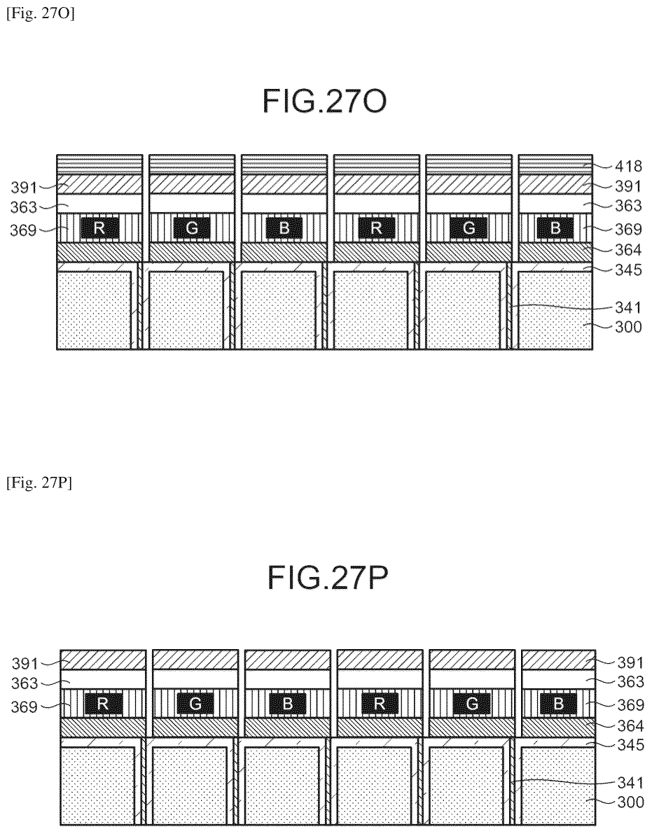

FIGS. 27A to 27P are diagrams illustrating an example of a method of manufacturing the light detecting device according to the seventh embodiment of the present disclosure. FIGS. 27A to 27P are diagrams illustrating a process of manufacturing a portion of the pixel 12 in the light detecting device 1. Note that FIGS. 27A to 27P illustrate an example of a process of manufacturing the pixel 12 including the element 240.

First, a semiconductor region 301 (not illustrated) and a wiring region 330 (not illustrated) are arranged in a semiconductor substrate 300. Next, a through electrode 341 and an insulating film 345 are disposed in the semiconductor substrate 300. Next, a third electrode 366 (not illustrated), a first electrode 361 (not illustrated), and an insulating film 365 (not illustrated) constituting the element 240 are disposed on the back surface side of the semiconductor substrate 300. Next, a material film 401 for a transparent semiconductor layer 364 is arranged (FIG. 27A).

Next, a material film 402 for a photoelectric conversion film 369 that absorbs red light, a material film 403 for a second electrode 363, and a material film 404 for a sealing film 391 are sequentially stacked on the back surface side of the semiconductor substrate 300 (FIG. 27B).

Next, a resist 405 is disposed on a surface of the material film 404. The resist 405 is formed to cover a region of a pixel 12a including a first photoelectric conversion unit 201 that absorbs red light (FIG. 27C).

Next, the material films 402 to 404 are etched using the resist 405 as a mask (FIG. 27D). As a result, the photoelectric conversion film 369, the second electrode 363, and the sealing film 391 of the first photoelectric conversion unit 201 of the pixel 12a are formed. Next, the resist 405 is removed (FIG. 27E).

Next, a material film 407 for a photoelectric conversion film 369 that absorbs green light, a material film 408 for a second electrode 363, and a material film 409 for a sealing film 391 are sequentially stacked on the back surface side of the semiconductor substrate 300 (FIG. 27F).

Next, a resist 411 is disposed on a surface of the material film 409. The resist 411 is formed to cover a region of a pixel 12b including a first photoelectric conversion unit 201 that absorbs green light (FIG. 27G).

Next, the material films 407 to 409 are etched (etched back) using the resist 411 as a mask (FIG. 27H). As a result, the photoelectric conversion film 369, the second electrode 363, and the sealing film 391 of the first photoelectric conversion unit 201 of the pixel 12b are formed. Next, the resist 411 is removed (FIG. 27I).

Next, a material film 413 for a photoelectric conversion film 369 that absorbs blue light, a material film 414 for a second electrode 363, and a material film 415 for a sealing film 391 are sequentially stacked on the back surface side of the semiconductor substrate 300 (FIG. 27J).

Next, a resist 417 is disposed on a surface of the material film 415. The resist 417 is formed to cover a region of a pixel 12c including a first photoelectric conversion unit 201 that absorbs blue light (FIG. 27K).

Next, the material films 413 to 415 are etched (etched back) using the resist 417 as a mask (FIG. 27L). As a result, the photoelectric conversion film 369, the second electrode 363, and the sealing film 391 of the first photoelectric conversion unit 201 of the pixel 12c are formed. Next, the resist 410 is removed (FIG. 27M).

Next, a resist 418 is disposed on the back surface side of the semiconductor substrate 300. The resist 418 is formed to cover the regions of the pixels 12 (the pixel 12a, the pixel 12b, and the pixel 12c) (FIG. 27N).

Next, the material film 401 is etched using the resist 418 as a mask (FIG. 27O). As a result, the transparent semiconductor layer 364 is formed. Next, the resist 418 is removed (FIG. 27P). Thereafter, an on-chip lens 393, etc. are formed. Through the above steps, the pixels 12 can be manufactured.

Since the other configurations of the light detecting device 1 are similar to those of the light detecting device 1 according to the first embodiment of the present disclosure, the description thereof will be omitted.

In this manner, the light detecting device 1 according to the seventh embodiment of the present disclosure includes a pixel 12 in which a first photoelectric conversion unit 201 absorbing visible light having a specific wavelength is arranged. As a result, the degree of freedom in designing the pixel 12 can be improved.

### 8. Eighth Embodiment

The light detecting device 7 according to the first embodiment described above includes a pixel 12 in which a first photoelectric conversion unit 201 absorbing visible light having a specific wavelength is arranged. On the other hand, a light detecting device 1 according to the eighth embodiment of the present disclosure is different from the light detecting device 1 according to the first embodiment described above in that a color filter is further included.

### <Configuration of Pixel>

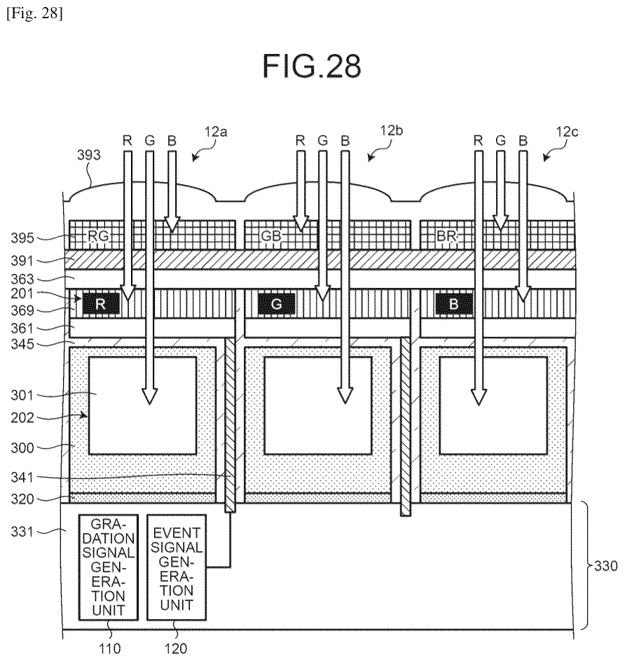

FIG. 28 is a cross-sectional view illustrating an example of a configuration of a pixel according to the eighth embodiment of the present disclosure. Similarly to FIG. 25, FIG. 28 is a cross-sectional view illustrating an example of a configuration of a pixel 12. The pixel 12 of FIG. 28 is different from the pixel 12 of FIG. 25 in that a color filter 395 is further arranged.

The color filter 395 transmits visible light including visible light having a specific wavelength and absorbed by the first photoelectric conversion unit 201. The color filter 395 is arranged in each of the pixel 12a, the pixel 12b, and the pixel 12c. A character attached to the color filter 395 in FIG. 28 represent the type of visible light allowed to transmit through the color filter 395. In FIG. 28, “RG” represents red light and green light. “GB” represents green light and blue light. “BR” represents blue light and red light. Note that a complementary color filter can be applied to the color filter 395.

In the pixel 12a, the color filter 395 transmits red light and green light. The first photoelectric conversion unit 201 of the pixel 12a absorbs the red light to perform photoelectric conversion, and the second photoelectric conversion unit 202 of the pixel 12a absorbs the green light to perform photoelectric conversion. In the pixel 12b, the color filter 395 transmits green light and blue light. The first photoelectric conversion unit 201 of the pixel 12b absorbs green light to perform photoelectric conversion, and the second photoelectric conversion unit 202 of the pixel 12b absorbs blue light to perform photoelectric conversion. In the pixel 12c, the color filter 395 transmits blue light and red light. The first photoelectric conversion unit 201 of the pixel 12c absorbs the blue light to perform photoelectric conversion, and the second photoelectric conversion unit 202 of the pixel 12c absorbs the red light to perform photoelectric conversion. A white arrow in FIG. 28 represents a trajectory of visible light (“R”: red light, “G”: green light, and “B”: blue light) incident on the pixel 12.

In this manner, by arranging the color filter 395 in the pixel 12, it is possible to attenuate visible light having a wavelength that is not used in the first photoelectric conversion unit 201 and the second photoelectric conversion unit 202 for each pixel 12.

### <Another Configuration of Pixel>

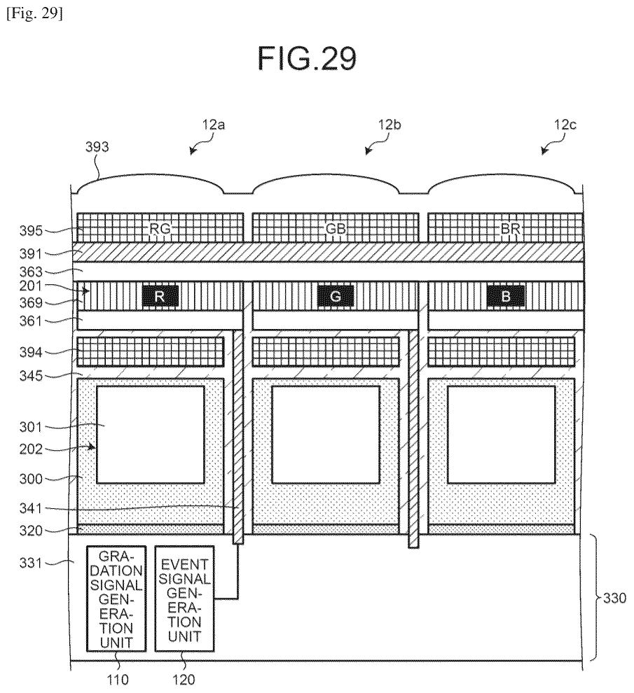

FIG. 29 is a cross-sectional view illustrating an example of another configuration of a pixel according to the eighth embodiment of the present disclosure. Similarly to FIG. 28, FIG. 29 is a cross-sectional view illustrating an example of a configuration of a pixel 12. FIG. 29 illustrates an example in which the pixel 12 (a pixel 12a, a pixel 12b, and a pixel 12c) further includes a color filter 394 described with reference to FIG. 22.

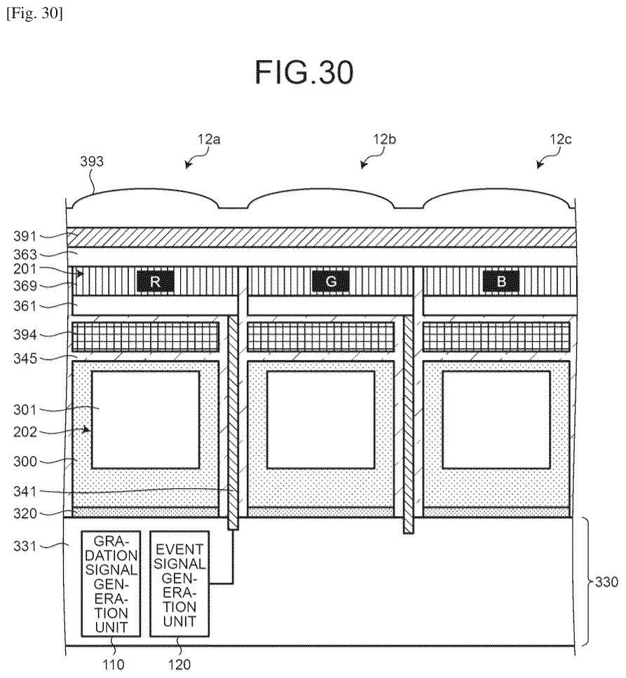

FIG. 30 is a cross-sectional view illustrating an example of another configuration of a pixel according to the eighth embodiment of the present disclosure. Similarly to FIG. 29, FIG. 30 is a cross-sectional view illustrating an example of a configuration of a pixel 12. The pixel 12 (a pixel 12a, a pixel 12b, and a pixel 12c) of FIG. 30 is different from the pixel 12 of FIG. 29 in that the color filter 395 is omitted.

Since the other configurations of the light detecting device 1 are similar to those of the light detecting device 1 according to the seventh embodiment of the present disclosure, the description thereof will be omitted.

In this manner, the light detecting device 1 according to the eighth embodiment of the present disclosure includes a pixel 12 in which a color filter is arranged. As a result, visible light that is not used in the first photoelectric conversion unit 201 and the second photoelectric conversion unit 202 of the pixel 12 can be attenuated. Noise in a gradation signal based on visible light can be reduced.

### 9. Ninth Embodiment

In the light detecting device 1 according to the seventh embodiment described above, the first photoelectric conversion unit 201 is connected to the event signal generation unit 120, and the second photoelectric conversion unit 202 is connected to the gradation signal generation unit 110. On the other hand, a light detecting device 1 according to the ninth embodiment of the present disclosure is different from the light detecting device 1 according to the seventh embodiment of the present disclosure described above in that the first photoelectric conversion unit 201 is connected to the gradation signal generation unit 110 and the second photoelectric conversion unit 202 is connected to the event signal generation unit 120.

### <Configuration of Pixel>

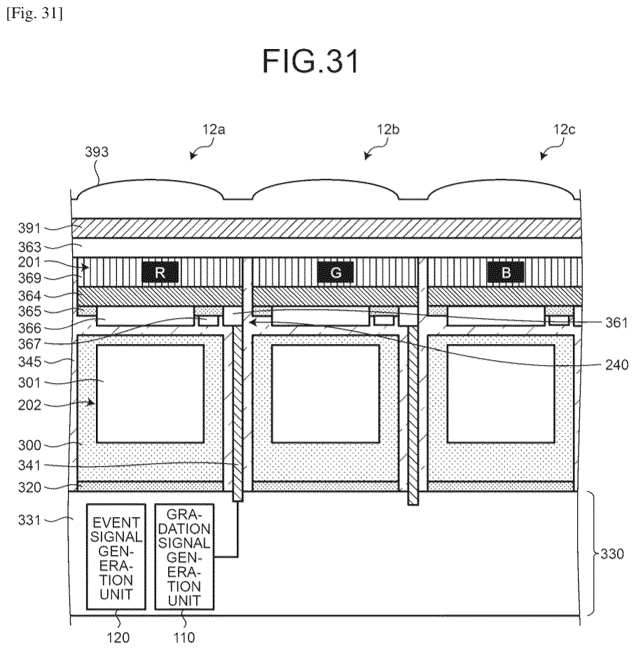

FIG. 31 is a cross-sectional view illustrating an example of a configuration of a pixel according to the ninth embodiment of the present disclosure. Similarly to FIG. 26, FIG. 31 is a cross-sectional view illustrating an example of a configuration of a pixel 12. As illustrated in FIG. 31, the gradation signal generation unit 110 is connected to the first photoelectric conversion unit 201 via the through electrode 341 and the element 240. On the other hand, the event signal generation unit 120 is connected to the second photoelectric conversion unit 202.

In the pixel 12 of FIG. 31, a gradation signal based on visible light absorbed by the first photoelectric conversion unit 201 is generated, and an event signal based on visible light or infrared light transmitted through the first photoelectric conversion unit 201 is generated.

### <Another Configuration of Pixel>

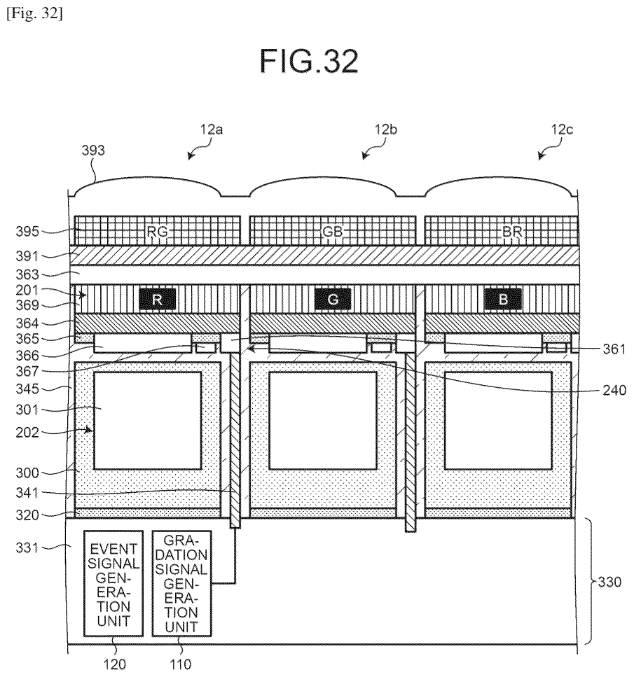

FIG. 32 is a cross-sectional view illustrating an example of another configuration of a pixel according to the ninth embodiment of the present disclosure. Similarly to FIG. 31, FIG. 32 is a cross-sectional view illustrating an example of a configuration of a pixel 12. FIG. 32 illustrates an example in which the pixel 12 (a pixel 12a, a pixel 12b, and a pixel 12c) further includes a color filter 395 described with reference to FIG. 28.

### <Another Configuration of Pixel>

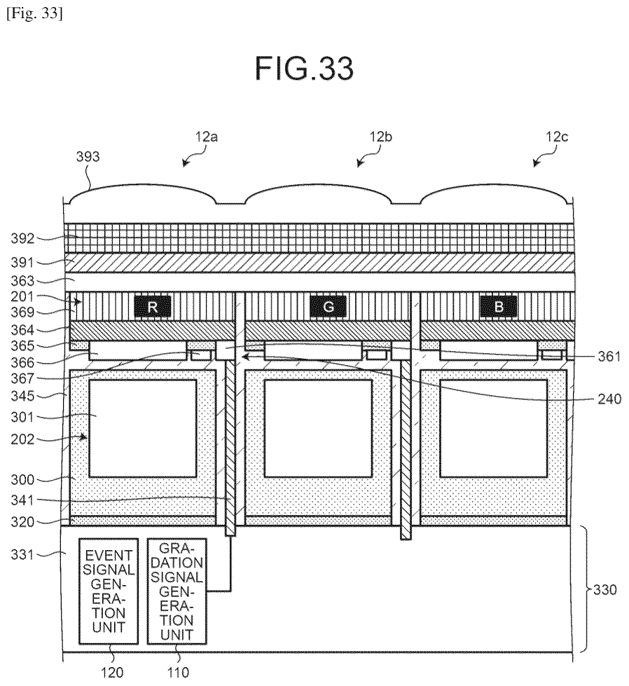

FIG. 33 is a cross-sectional view illustrating an example of another configuration of a pixel according to the ninth embodiment of the present disclosure. Similarly to FIG. 32, FIG. 33 is a cross-sectional view illustrating an example of a configuration of a pixel 12. FIG. 33 illustrates an example in which the pixel 12 (a pixel 12a, a pixel 12b, and a pixel 12c) includes a color filter 392 instead of the color filter 395.

Since the other configurations of the light detecting device 1 are similar to those of the light detecting device 1 according to the seventh embodiment of the present. disclosure, the description thereof will be omitted.

In this manner, in the light detecting device 1 according to the ninth embodiment of the present disclosure, the first photoelectric conversion unit 201 constituted by the photoelectric conversion film 369 is connected to the gradation signal generation unit 110. In addition, the second photoelectric conversion unit 202 formed in the semiconductor substrate 300 is connected to the event signal generation unit 120.

### 10. Others

Portions other than the pixel array unit 13 will be described.

### <Configuration of Current-Voltage Conversion Circuit>

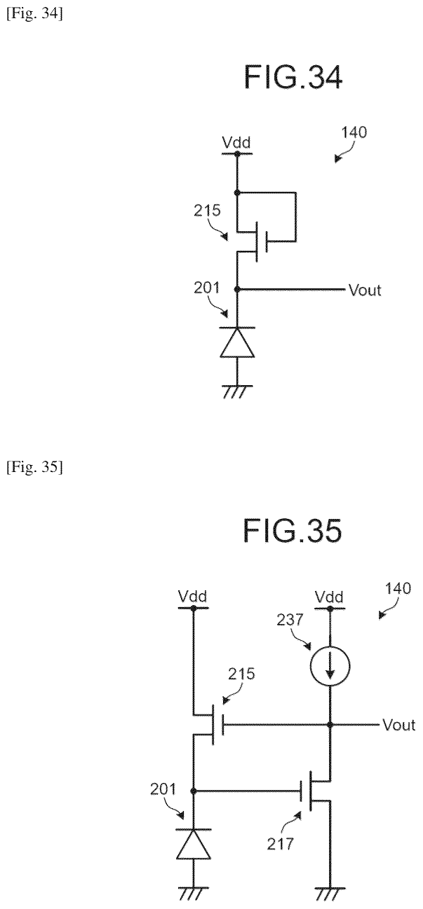

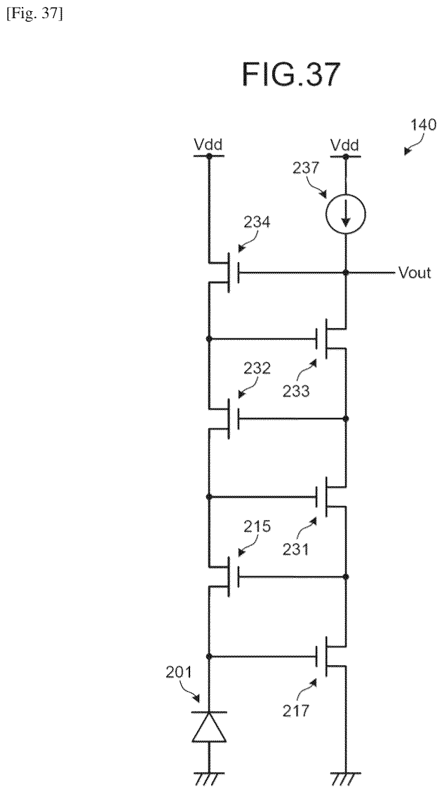

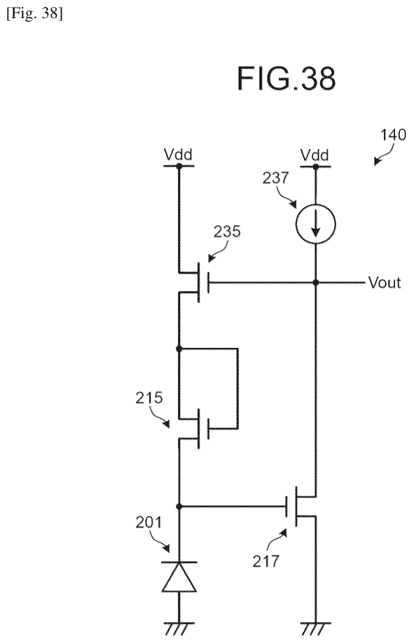

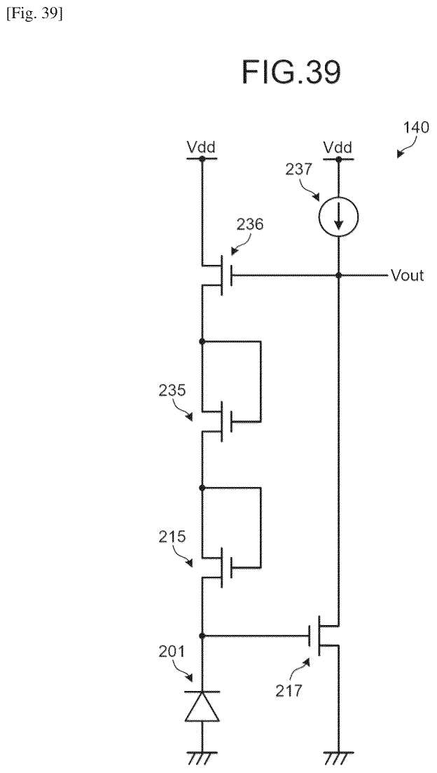

FIGS. 34 to 39 are diagrams illustrating examples of configurations of current-voltage conversion circuits according to modifications of the embodiment of the present disclosure.

FIG. 34 illustrates an example of a current-voltage conversion circuit 140 constituted by the first photoelectric conversion unit 201 and the MOS transistor 215. The MOS transistor 215 constitutes a constant current circuit.

FIG. 35 illustrates an example of a current-voltage conversion circuit 140 having the same configuration as that of FIG. 5. A constant current circuit 237 is disposed instead of the MOS transistor 216.

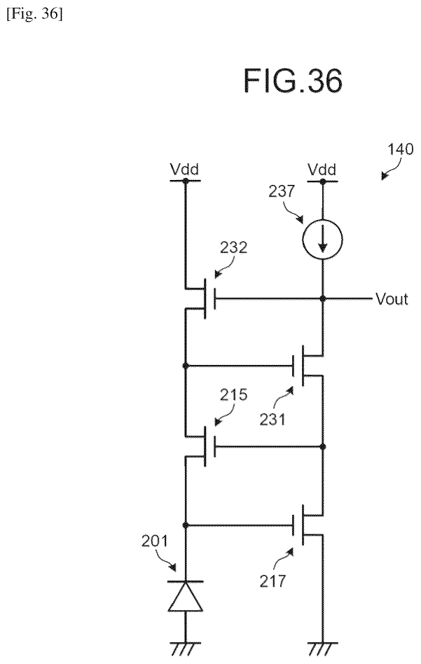

FIGS. 36 to 39 illustrate examples of current-voltage conversion circuits 140 in which MOS transistors are additionally connected to the drain sides of the MOS transistor 215 and the like. By increasing the number of additionally connected MOS transistors, it is possible to increase an amplification factor when a change in current of the first photoelectric conversion unit 201 is converted into a voltage. As a result, the influence of noise can be reduced.

### <Method of Generating Gradation Signal and Event Signal>

FIG. 40 is a diagram illustrating an example of generation of gradation signals and event signals according to an embodiment of the present disclosure. FIG. 40 illustrates timings at which gradation signals and event signals are generated. The gradation signal generation timings are illustrated on the upper side of FIG. 40, and the event signal generation timings are illustrated on the lower side of FIG. 40. In FIG. 40, a “vertical synchronization signal 1” is a signal indicating the delimitation between frame periods in generating gradation signals. Furthermore, a “vertical synchronization signal 2” is a signal indicating the delimitation between frame periods in generating event signals.

In the generation of the gradation signals, shutter 501, exposure 502, and reading 503 are sequentially performed for each row to generate a gradation signal. The gradation signal is generated for each row from the first row to the last row by performing the shutter 501, the exposure 502, and the reading 503 at staggered timings, and the frame period for gradation signals ends.

On the other hand, the event signals are generated by performing on-event detection 504, off-event detection 505, and AZ operation 506 for all pixels 12. Next, reading 507, which is outputting an event signal, is performed sequentially for each row, and the frame period for event signals ends. As illustrated in FIG. 40, the generation of the gradation signals and the generation of the event signals can be performed asynchronously at different frame rates.

### 11. Configuration of Electronic Device

The light detecting device 1 described above can be applied to various electronic devices such as an imaging system, e.g., a digital still camera or a digital video camera, a mobile phone having an imaging function, or another device having an imaging function.

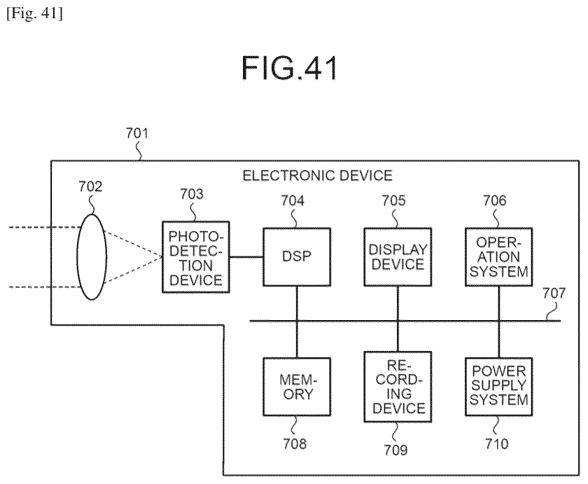

FIG. 41 is a block diagram illustrating an example of a configuration of an imaging device mounted on an electronic device. As illustrated in FIG. 41, an electronic device 701 includes an optical system 702, a light detecting device 703, and a digital signal processor (DSP) 704, is configured in such a manner that the DSP 704, a display device 705, an operation system 706, a memory 708, a recording device 709, and a power supply system 710 are connected to each other via a bus 707, and is capable of capturing a still image and a moving image.

The optical system 702 includes one or more lenses, guides image light (incident light) from a subject to the light detecting device 703, and forms an image on a light receiving surface (sensor unit) of the light detecting device 703.

The light detecting device 1 having a configuration in any of the above-described examples is applied to the light detecting device 703. In the light detecting device 703, electrons are accumulated for a certain period according to an image formed on the light receiving surface via the optical system 702. Then, a signal corresponding to the electrons accumulated in the light detecting device 703 is input to the DSP 704.

The DSP 704 performs various types of signal processing on the signal from the light detecting device 703 to acquire an image, and temporarily stores the image data in the memory 708. The image data stored in the memory 708 is recorded in the recording device 709, or supplied to the display device 705 to display the image. In addition, the operation system 706 receives various operations performed by a user and supplies an operation signal to each block of the electronic device 701, and the power supply system 710 supplies power necessary for driving each block of the electronic device 701.

### 12. Example of Application to Mobile Body

The technology according to the present disclosure (present technology) can be applied to various products. For example, the technology according to the present disclosure may be realized as a device mounted on any type of mobile body such as an automobile, an electric vehicle, a hybrid electric vehicle, a motorcycle, a bicycle, a personal mobility, an airplane, a drone, a ship, or a robot.

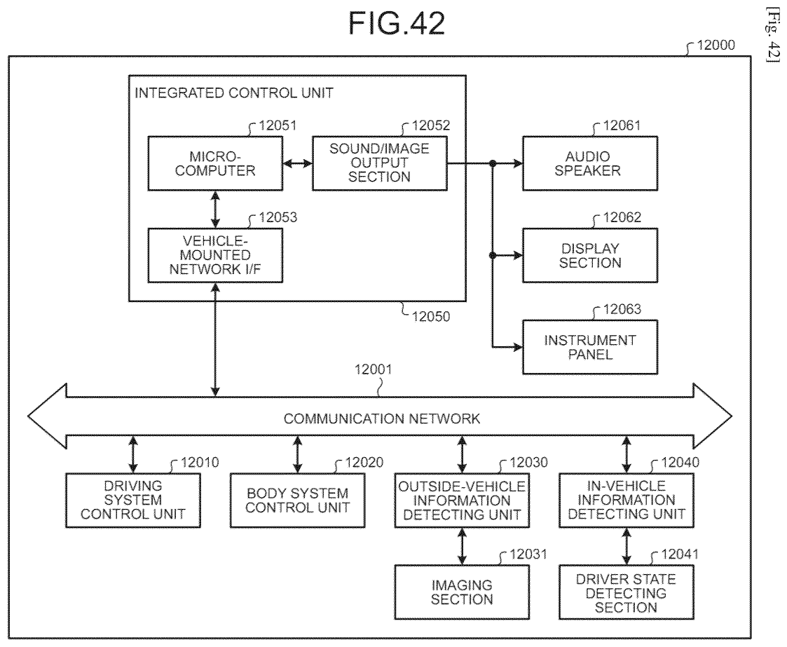

FIG. 42 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 42, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 42, an audio speaker 12061, a display section 12062, and an instrument panel 12063 are illustrated as the output device. The display section 12062 may, for example, include at least one of an on-board display and a head-up display.

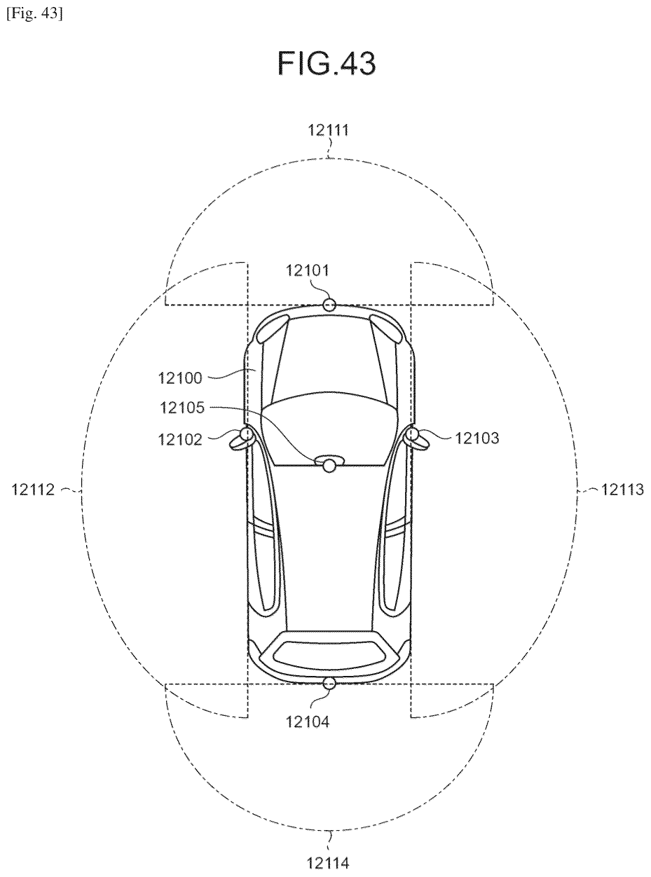

FIG. 43 is a diagram depicting an example of the installation position of the imaging section 12031.

In FIG. 43, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of a vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 43 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by super-imposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to, for example, the imaging section 12031 among the above-described components. Specifically, the light detecting device 1 of FIG. 1 can be applied to the imaging section 12031.

### 13. Example of Application to Endoscopic Surgery System

The technology according to the present disclosure (present technology) can be applied to various products. For example, the technology according to the present disclosure may be applied to an endoscopic surgery system.

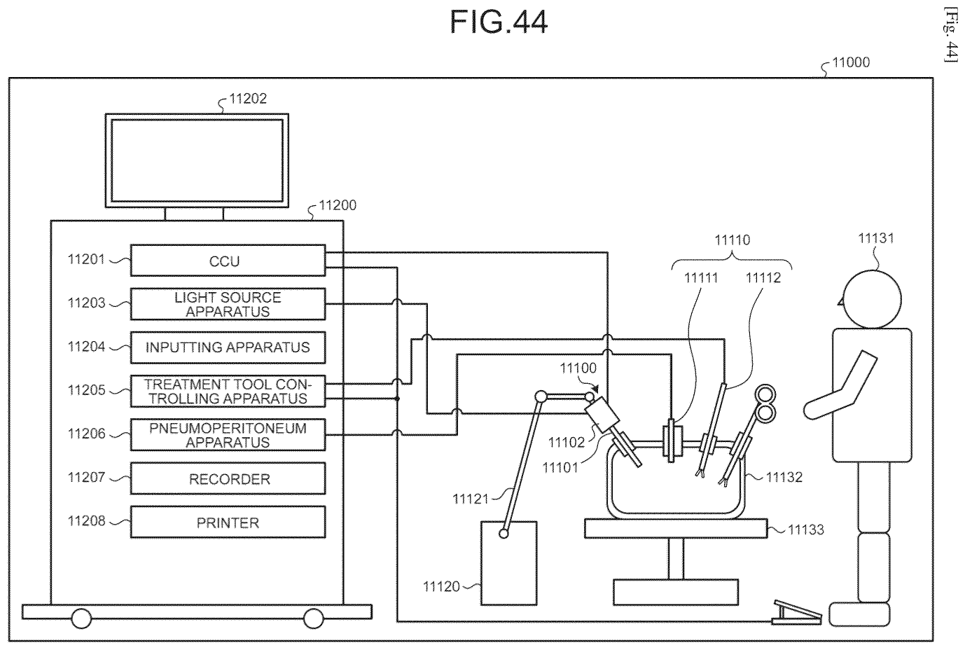

FIG. 44 is a view depicting an example of a schematic configuration of an endoscopic surgery system to which the technology according to an embodiment of the present disclosure (present technology) can be applied.

In FIG. 44, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy treatment tool 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body lumen of the patient 11132, and a camera head 11102 connected to a proximal end of the lens barrel 11101. In the example depicted, the endoscope 11100 is depicted which includes as a hard mirror having the lens barrel 11101 of the hard type. However, the endoscope 11100 may otherwise be included as a soft mirror having the lens barrel 11101 of the soft type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body lumen of the patient 11132 through the objective lens. It is to be noted that the endoscope 11100 may be a direct view mirror or may be a perspective view mirror or a side view mirror.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy treatment tool 11112 for cautery or incision of a tissue, sealing of a blood vessel or the like. A pneumoperitoneum apparatus 11206 feeds gas into a body lumen of the patient 11132 through the pneumoperitoneum tube 11111 to inflate the body lumen in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a pre-determined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alter-natively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

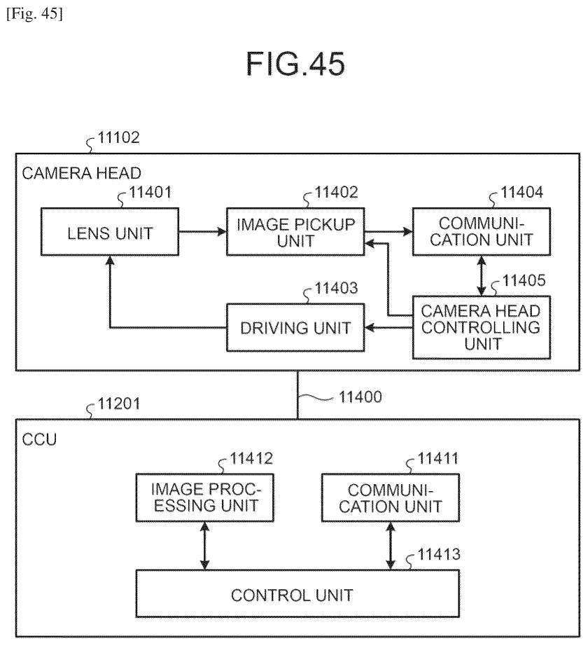

FIG. 45 is a block diagram depicting an example of a functional configuration of the camera head 11102 and the CCU 11201 depicted in FIG. 44.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera bead 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy treatment tool 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure can be applied has been described above. The technology according to the present disclosure can be applied to, for example, the endoscope 11100 or the image pickup unit 11402 of the camera bead 11102 among the above-described components. Specifically, the light detecting device 1 of FIG. 1 can be applied to the image pickup unit 11402.

Note that although the endoscopic surgery system has been described as an example here, the technology according to the present disclosure may also be applied to, for example, another microscopic surgery system or the like.

Note that the configuration according to the third embodiment of the present disclosure can be applied to the other embodiments. Specifically, the color filter 394 in FIG. 22 can be applied to the second to fifth embodiments of the present disclosure. Furthermore, the configuration of the pixel 12 in which the color filter of FIG. 23 is omitted can be applied to the second to fifth embodiments of the present disclosure. Furthermore, the first photoelectric conversion unit 201 and the second photoelectric conversion unit 202 of FIG. 24 can be applied to the second to fifth embodiments of the present disclosure.

Note that the configuration according to the third embodiment of the present disclosure can be applied to the other embodiments. Specifically, the element 240 of FIG. 9 can be applied to the second and fifth embodiments of the present disclosure.

Note that the configuration according to the seventh embodiment of the present disclosure can be applied to the other embodiments. Specifically, the first photoelectric conversion unit 201 of FIG. 25 can be applied to the first to sixth embodiments of the present disclosure.

Note that the configuration according to the eighth embodiment of the present disclosure can be applied to the other embodiments. Specifically, the first photoelectric conversion unit 201 and the color filter 395 of FIG. 28 can be applied to the first to sixth embodiments of the present disclosure.

Note that the present technology can also take the following configurations.

(1)

A photodetection device comprising:
a first photoelectric conversion unit stacked in a semiconductor substrate and configured to perform photoelectric conversion of incident light; and
an event signal generation unit configured to detect a change in luminance of the incident light in a same direction as an event on the basis of a charge generated by the photoelectric conversion of the first photoelectric conversion unit, and generates an event signal that is a signal based on the detected event.
   (2)

The photodetection device according to the above (1), wherein the event signal generation unit is disposed in the semiconductor substrate.

(3)

The photodetection device according to the above (1), wherein the event signal generation unit includes an element connected to the first photoelectric conversion unit, the element including a semiconductor layer disposed adjacent to the first photoelectric conversion unit.

(4)

The photodetection device according to any one of the above (1) to (3), further comprising a gradation signal generation unit configured to generate a gradation signal that is a signal corresponding to a luminance of the incident light.

(5)

The photodetection device according to the above (4), wherein the gradation signal generation unit is disposed in the semiconductor substrate.

(6)

The photodetection device according to the above (4) or (5), wherein the gradation signal generation unit generates the gradation signal on the basis of the charge generated by the photoelectric conversion of the first photoelectric conversion unit.

(7)

The photodetection device according to the above (6), further comprising a first connection circuit configured to connect the first photoelectric conversion unit to the event signal generation unit and the gradation signal generation unit.

(8)

The photodetection device according to the above (7), wherein the first connection circuit includes an element connected to the first photoelectric conversion unit, the element including a semiconductor layer disposed adjacent to the first photoelectric conversion unit.

(9)

The photodetection device according to the above (7), wherein the event signal generation unit detects the event on the basis of a charge of the first photoelectric conversion unit supplied via the first connection circuit, and
the gradation signal generation unit generates the gradation signal on the basis of a charge of the first photoelectric conversion unit supplied via the first connection circuit.
   (10)

The photodetection device according to the above (9), further comprising a second photoelectric conversion unit disposed in the semiconductor substrate and configured to perform photoelectric conversion of incident light.

(11)

The photodetection device according to the above (10), wherein the event signal generation unit generates the event signal on the basis of a charge generated by the photoelectric conversion of the second photoelectric conversion unit and a charge of the first photoelectric conversion unit supplied via the first connection circuit.

(12)

The photodetection device according to the above (10), wherein the gradation signal generation unit generates the gradation signal on the basis of a charge generated by the photoelectric conversion of the second photoelectric conversion unit and a charge of the first photoelectric conversion unit supplied via the first connection circuit.

(13)

The photodetection device according to the above (4), wherein the gradation signal generation unit generates the gradation signal on the basis of a charge generated by photoelectric conversion of a second photoelectric conversion unit disposed in the semiconductor substrate and configured to perform photoelectric conversion of incident light.

(14)

The photodetection device according to (13), wherein the first photoelectric conversion unit is configured to have a size different from a size of the second photoelectric conversion unit.

(15)

The photodetection device according to (13), wherein the second photoelectric conversion unit performs photoelectric conversion of the incident light transmitted through the first photoelectric conversion unit.

(16)

The photodetection device according to (13), wherein the event signal generation unit includes an element connected to the first photoelectric conversion unit, the element including a semiconductor layer disposed adjacent to the first photoelectric conversion unit.

(17)

The photodetection device according to the above (4), further comprising:
a second photoelectric conversion unit disposed in the semiconductor substrate and configured to perform photoelectric conversion of incident light; and
a second connection circuit that connects the second photoelectric conversion unit to the event signal generation unit and the gradation signal generation unit,
wherein the event signal generation unit generates the event signal on the basis of the charge generated by the photoelectric conversion of the first photoelectric conversion unit and a charge of the second photoelectric conversion unit supplied via the second connection circuit, and
the gradation signal generation unit generates the gradation signal on the basis of the charge of the second photoelectric conversion unit supplied via the second connection circuit.
   (18)

The photodetection device according to the above (4), further comprising:
a second photoelectric conversion unit disposed in the semiconductor substrate and configured to perform photoelectric conversion of incident light,
wherein the first photoelectric conversion unit performs the photoelectric conversion by absorbing visible light having a specific wavelength with respect to visible light included in the incident light, and
the second photoelectric conversion unit performs the photoelectric conversion of the visible light transmitted through the first photoelectric conversion unit.
   (19)

The photodetection device according to the above (18), further comprising:
a color filter configured to transmit visible light including the visible light having the specific wavelength in the incident light,
wherein the first photoelectric conversion unit performs the photoelectric conversion of the visible light having the specific wavelength transmitted through the color filter, and
the second photoelectric conversion unit performs the photoelectric conversion of the visible light transmitted through the color filter and the first photoelectric conversion unit.
   (20)

A photodetection device comprising:
a first photoelectric conversion unit stacked in a semiconductor substrate and configured to perform photoelectric conversion of incident light;
a gradation signal generation unit configured to generate a gradation signal that is a signal corresponding to a luminance of the incident light on the basis of a charge generated by the photoelectric conversion of the first photoelectric conversion unit; and
an event signal generation unit configured to detect a change in luminance of the incident light in a same direction as an event, and generate an event signal that is a signal based on the detected event.
   (21)

The photodetection device according to the above (20), wherein the gradation signal generation unit is disposed in the semiconductor substrate.

(22)

The photodetection device according to the above (20), wherein the event signal generation unit is disposed in the semiconductor substrate.

(23)

The photodetection device according to the above (20), further comprising a second photoelectric conversion unit disposed in the semiconductor substrate and configured to perform photoelectric conversion of the incident light.

(24)

The photodetection device according to the above (23) further comprising:
a first connection circuit configured to connect the first photoelectric conversion unit to the event signal generation unit and the gradation signal generation unit,
wherein the gradation signal generation unit generates the gradation signal on the basis of a charge of the first photoelectric conversion unit supplied via the first connection circuit, and
the event signal generation unit detects the event on the basis of a charge generated by the photoelectric conversion of the second photoelectric conversion unit and a charge of the first photoelectric conversion unit supplied via the first connection circuit.
   (25)

The photodetection device according to the above (23), wherein the event signal generation unit generates the event signal on the basis of a charge generated by the photoelectric conversion of the second photoelectric conversion unit.

(26)

The photodetection device according to the above (25) further comprising:
a second connection circuit configured to connect the second photoelectric conversion unit to the event signal generation unit and the gradation signal generation unit,
wherein the gradation signal generation unit generates the gradation signal on the basis of a charge generated by the photoelectric conversion of the first photoelectric conversion unit and a charge of the second photoelectric conversion unit supplied via the second connection circuit, and
the event signal generation unit detects the event on the basis of a charge of the second photoelectric conversion unit supplied via the second connection circuit.
   (27)

The photodetection device according to the above (25), wherein the first photoelectric conversion unit is configured to have a size different from a size of the second photoelectric conversion unit.

(28)

The photodetection device according to the above (25), wherein the second photoelectric conversion unit performs photoelectric conversion of the incident light transmitted through the first photoelectric conversion unit.

(29)

The photodetection device according to above (23), wherein
the first photoelectric conversion unit performs the photoelectric conversion by absorbing visible light having a specific wavelength with respect to visible light included in the incident light, and
the second photoelectric conversion unit performs the photoelectric conversion of the visible light transmitted through the first photoelectric conversion unit.
   (30)

The photodetection device according to above (29), further comprising:
a color filter configured to transmit visible light including the visible light having the specific wavelength in the incident light,
wherein the first photoelectric conversion unit performs the photoelectric conversion of the visible light having the specific wavelength transmitted through the color filter, and
the second photoelectric conversion unit performs the photoelectric conversion of the visible light transmitted through the color filter and the first photoelectric conversion unit.

Note that the present technology can also take the following configurations.

(1)

A light detecting device comprising:
a semiconductor substrate; and
a pixel including an event signal generation circuit and a first photoelectric conversion circuit, wherein
the first photoelectric conversion circuit is configured to perform photoelectric conversion of incident light to generate a first charge based on a first change in luminance of the incident light, and
the event signal generation circuit is configured to detect the change in luminance based on the first charge and generate an event signal based on the first change.
   (2)

The light detecting device according to the above (1), wherein the first photoelectric conversion circuit includes a first electrode, a second electrode and a photoelectric conversion layer.

(3)

The light detecting device according to the above (2), wherein the photoelectric conversion layer includes an organic material.

(4)

The light detecting device according to the above (3), wherein the first photoelectric conversion circuit includes a semiconductor layer.

(5)

The light detecting device according to the above (4), wherein the semiconductor layer includes a transparent material.

(6)

The light detecting device according to any one of the above (1) to (5), wherein the first photoelectric conversion circuit is stacked on the semiconductor substrate or is disposed in the semiconductor substrate.

(7)

The light detecting device according to the above (6), wherein a second photoelectric conversion circuit is disposed on the semiconductor substrate or is stacked on the semiconductor substrate, and wherein the second photoelectric conversion circuit performs is configured to generate a second charge for generating a gradation signal.

(8)

The light detecting device according to any one of the above (1) to (7), wherein the event signal generation circuit is arranged in or on the semiconductor substrate.

(9)

The light detecting device according to any one of the above (1) to (8), wherein the semiconductor substrate includes silicon.

(10)

The light detecting device according to any one of the above (1) to (9), wherein the first photoelectric conversion circuit is connected to the event signal generation circuit via a through electrode.

(11)

The light detecting device according to any one of the above (1) to (10), wherein the pixel includes a second photoelectric conversion circuit.

(12)

The light detecting device according to the above (11), wherein the first photoelectric conversion circuit and the second photoelectric conversion circuit are different sizes in a plan view.

(13)

The light detecting device according to the above (12), wherein the first photoelectric conversion circuit is four times larger than the second photoelectric conversion circuit.

(14)

The light detecting device according to any one of the above (1) to (13), wherein the pixel includes a shared floating diffusion region for a plurality of photodiodes of the first photoelectric conversion circuit.

(15)

The light detecting device according to the above (14), wherein the pixel includes a plurality of transfer elements.

(16)

The light detecting device according to the above (14), wherein the pixel includes a plurality of elements which respectively perform reset and amplification.

(17)

The light detecting device according to any one of the above (1) to (16), wherein the pixel includes a gradation signal generation circuit configured to generate a gradation signal based on the charge.

(18)

The light detecting device according to the above (17), wherein the gradation signal generation circuit is arranged in or on the semiconductor substrate.

(19)

The light detecting device according to the above (17), wherein the event signal generation circuit and the gradation signal generation circuit share the first photoelectric conversion circuit.

(20)

The light detecting device according to the above (17), wherein a circuit connects the first photoelectric conversion circuit to the event signal generation circuit and the gradation signal generation circuit.

(21)

The light detecting device according to the above (20), wherein the circuit comprises a first transfer element and a second transfer element, which connect the event signal generation circuit and the gradation signal generation circuit, and an output of the first photoelectric conversion circuit is connected between the first transfer element and the second transfer element.

(22)

The light detecting device according to any one of the above (1) to (21), wherein the event signal generation circuit includes a current-voltage conversion circuit comprising an amplification element.

(23)

The light detecting device according to the above (22), wherein the current-voltage conversion circuit is configured with one or more additional elements configured to increase an amplification factor of a change in current of the first photoelectric conversion circuit.

(24)

The light detecting device according to any one of the above (1) to (23), further comprising a color filter layer over or under an organic film layer.

(25)

The light detecting device according to the above (24), further comprising an on chip lens over the color filter layer.

(26)

The light detecting device according to the above (25), wherein the first photoelectric conversion circuit performs photoelectric conversion of infrared light transmitted by each color filter arranged in the pixel and a second photoelectric conversion circuit performs photoelectric conversion of visible light transmitted through the first photoelectric conversion circuit and the color filter.

(27)

The light detecting device according to any one of the above (1) to (26), wherein the first photoelectric conversion circuit performs photoelectric conversion of infrared light.

(28)

The light detecting device according to any one of the above (1) to (27), wherein the first photoelectric conversion circuit includes a plurality of photodiodes.

(29)

The light detecting device according to the above (28), wherein the pixel includes a connection circuit switchably connecting the first photoelectric conversion circuit to the event signal generation circuit and a gradation signal generation circuit configured to generate a gradation signal.

(30)

The light detecting device according to the above (29), wherein
a second photoelectric conversion circuit in the semiconductor substrate includes a plurality of photodiodes, and
the second photoelectric conversion circuit outputs a signal to the gradation signal generation circuit.
   (31)

The light detecting device according to the above (30), wherein an organic film layer is between a color filter layer and the semiconductor substrate.

(32)

The light detecting device according the the above (29), wherein
a second photoelectric conversion circuit in the semiconductor substrate includes a plurality of photodiodes, and
the pixel includes a connection circuit switchably connecting the second photoelectric conversion circuit to the event signal generation circuit and a gradation signal generation circuit configured to generate a gradation signal.
   (33)

The light detecting device according to the above (32), wherein the color filter layer is between an organic film layer and the semiconductor substrate.

(34)

The light detecting device according to any one of the above (1) to (33), wherein
the pixel incudes a second photoelectric conversion circuit in the semiconductor substrate, which outputs a signal to the event signal generation circuit,
the event signal generation circuit is arranged in or on the semiconductor substrate, and
the first photoelectric conversion circuit outputs a signal to a gradation signal generation circuit in the pixel.
   (35)

The light detecting device according to the above (34), wherein the first photoelectric conversion circuit detects a first light wavelength and the second photoelectric conversion circuit detects a second light wavelength.

(36)

A light detecting device comprising:
a semiconductor substrate; and
a first photoelectric conversion circuit disposed in the semiconductor substrate or stacked on the semiconductor substrate; wherein
the first photoelectric conversion circuit is configured to output a signal for a gradation signal or an event signal switchably.
   (37)

The light detecting device according to the above (36), wherein the first photoelectric conversion circuit includes a first electrode, a second electrode and an organic photoelectric conversion film.

(38)

The light detecting device according to the above (37), wherein the first photoelectric conversion circuit includes a semiconductor layer.

(39)

The light detecting device according to any one of the above (36) to (38), wherein the pixel includes an event signal generation circuit and a gradation signal generation circuit, and the first photoelectric conversion circuit connects both the event signal generation circuit and the gradation signal generation circuit.

(40)

A light detecting device comprising:
a semiconductor substrate;
a pixel including a first photoelectric conversion circuit and a second photoelectric conversion circuit, wherein
one of the first photoelectric conversion circuit and the second photoelectric conversion circuit is configured to generate a charge based on a first incident light for generating an event signal, and
the other of the first photoelectric conversion circuit and the second photoelectric conversion circuit is configured to generate a charge based on a second incident light for generating a gradation signal.
   (41)

The light detecting device according to the above (40), wherein the first photoelectric conversion circuit is stacked on the semiconductor substrate.

(42)

The light detecting device according to the above (41), wherein the second photoelectric conversion circuit is disposed in the semiconductor substrate.

(43)

The light detecting device according to any one of the above (40) to (42), wherein a circuit for generating the event signal is disposed in the semiconductor substrate.

(44)

The light detecting device according to the above (43), wherein a circuit for generating the gradation signal is disposed in the semiconductor substrate.

### REFERENCE SIGNS LIST

1, 703 Light detecting device
110 Gradation signal generation unit
120 Event signal generation unit
201 First photoelectric conversion unit
202 Second photoelectric conversion unit
260 First connection circuit
261 Second connection circuit
300 Semiconductor substrate
392, 394, 395 Color filter
11402, 12031, 12101 to 12105 Image pickup unit, Imaging section

1. A light detecting device comprising:
a semiconductor substrate; and
a pixel including an event signal generation circuit and a first photoelectric conversion circuit, wherein
the first photoelectric conversion circuit is configured to perform photoelectric conversion of incident light to generate a first charge based on a first change in luminance of the incident light, and
the event signal generation circuit is configured to detect the change in luminance based on the first charge and generate an event signal based on the first change.

2. The light detecting device of claim 1, wherein the first photoelectric conversion circuit includes a first electrode, a second electrode and a photoelectric conversion layer.

3. The light detecting device of claim 2, wherein the photoelectric conversion layer includes an organic material.

4. The light detecting device of claim 3, wherein the first photoelectric conversion circuit includes a semiconductor layer.

5. The light detecting device of claim 4, wherein the semiconductor layer includes a transparent material.

6. The light detecting device of claim 1, wherein the first photoelectric conversion circuit is stacked on the semiconductor substrate or is disposed in the semiconductor substrate.

7. The light detecting device of claim 6, wherein a second photoelectric conversion circuit is disposed on the semiconductor substrate or is stacked on the semiconductor substrate, and wherein the second photoelectric conversion circuit performs is configured to generate a second charge for generating a gradation signal.

8. The light detecting device of claim 1, wherein the event signal generation circuit is arranged in or on the semiconductor substrate.

9. The light detecting device of claim 1, wherein the semiconductor substrate includes silicon.

10. The light detecting device of claim 1, wherein the first photoelectric conversion circuit is connected to the event signal generation circuit via a through electrode.

11. The light detecting device of claim 1, wherein the pixel includes a second photoelectric conversion circuit.

12. The light detecting device of claim 11, wherein the first photoelectric conversion circuit and the second photoelectric conversion circuit are different sizes in a plan view.

13. The light detecting device of claim 12, wherein the first photoelectric conversion circuit is four times larger than the second photoelectric conversion circuit.

14. The light detecting device of claim 1, wherein the pixel includes a shared floating diffusion region for a plurality of photodiodes of the first photoelectric conversion circuit.

15. The light detecting device of claim 14, wherein the pixel includes a plurality of transfer elements.

16. The light detecting device of claim 14, wherein the pixel includes a plurality of elements which respectively perform reset and amplification.

17. The light detecting device of claim 1, wherein the pixel includes a gradation signal generation circuit configured to generate a gradation signal based on the charge.

18. The light detecting device of claim 17, wherein the gradation signal generation circuit is arranged in or on the semiconductor substrate.

19. The light detecting device of claim 17, wherein the event signal generation circuit and the gradation signal generation circuit share the first photoelectric conversion circuit.

20. The light detecting device of claim 17, wherein a circuit connects the first photoelectric conversion circuit to the event signal generation circuit and the gradation signal generation circuit.

21. The light detecting device of claim 20, wherein the circuit comprises a first transfer element and a second transfer element, which connect the event signal generation circuit and the gradation signal generation circuit, and an output of the first photoelectric conversion circuit is connected between the first transfer element and the second transfer element.

22. The light detecting device of claim 1, wherein the event signal generation circuit includes a current-voltage conversion circuit comprising an amplification element.

23. The light detecting device of claim 22, wherein the current-voltage conversion circuit is configured with one or more additional elements configured to increase an amplification factor of a change in current of the first photoelectric conversion circuit.

24. The light detecting device of claim 1, further comprising a color filter layer over or under an organic film layer.

25. The light detecting device of claim 24, further comprising an on chip lens over the color filter layer.

26. The light detecting device of claim 25, wherein the first photoelectric conversion circuit performs photoelectric conversion of infrared light transmitted by each color filter arranged in the pixel and a second photoelectric conversion circuit performs photoelectric conversion of visible light transmitted through the first photoelectric conversion circuit and the color filter.

27. The light detecting device of claim 1, wherein the first photoelectric conversion circuit performs photoelectric conversion of infrared light.

28. The light detecting device of claim 1, wherein the first photoelectric conversion circuit includes a plurality of photodiodes.

29. The light detecting device of claim 28, wherein the pixel includes a connection circuit switchably connecting the first photoelectric conversion circuit to the event signal generation circuit and a gradation signal generation circuit configured to generate a gradation signal.

30. The light detecting device of claim 29, wherein
a second photoelectric conversion circuit in the semiconductor substrate includes a plurality of photodiodes, and
the second photoelectric conversion circuit outputs a signal to the gradation signal generation circuit.

31. The light detecting device of claim 30, wherein an organic film layer is between a color filter layer and the semiconductor substrate.

32. The light detecting device of claim 29, wherein
a second photoelectric conversion circuit in the semiconductor substrate includes a plurality of photodiodes, and
the pixel includes a connection circuit switchably connecting the second photoelectric conversion circuit to the event signal generation circuit and a gradation signal generation circuit configured to generate a gradation signal.

33. The light detecting device of claim 32, wherein the color filter layer is between an organic film layer and the semiconductor substrate.

34. The light detecting device of claim 1, wherein
the pixel incudes a second photoelectric conversion circuit in the semiconductor substrate, which outputs a signal to the event signal generation circuit,
the event signal generation circuit is arranged in or on the semiconductor substrate, and
the first photoelectric conversion circuit outputs a signal to a gradation signal generation circuit in the pixel.

35. The light detecting device of claim 34, wherein the first photoelectric conversion circuit detects a first light wavelength and the second photoelectric conversion circuit detects a second light wavelength.

36. A light detecting device comprising:
a semiconductor substrate; and
a first photoelectric conversion circuit disposed in the semiconductor substrate or stacked on the semiconductor substrate; wherein
the first photoelectric conversion circuit is configured to output a signal for a gradation signal or an event signal switchably.

37. The light detecting device of claim 36, wherein the first photoelectric conversion circuit includes a first electrode, a second electrode and an organic photoelectric conversion film.

38. The light detecting device of claim 37, wherein the first photoelectric conversion circuit includes a semiconductor layer.

39. The light detecting device of claim 36, wherein the pixel includes an event signal generation circuit and a gradation signal generation circuit, and the first photoelectric conversion circuit connects both the event signal generation circuit and the gradation signal generation circuit.

40. A light detecting device comprising:
a semiconductor substrate;
a pixel including a first photoelectric conversion circuit and a second photoelectric conversion circuit, wherein
one of the first photoelectric conversion circuit and the second photoelectric conversion circuit is configured to generate a charge based on a first incident light for generating an event signal, and
the other of the first photoelectric conversion circuit and the second photoelectric conversion circuit is configured to generate a charge based on a second incident light for generating a gradation signal.

41. The light detecting device of claim 40, wherein the first photoelectric conversion circuit is stacked on the semiconductor substrate.

42. The light detecting device of claim 41, wherein the second photoelectric conversion circuit is disposed in the semiconductor substrate.

43. The light detecting device of claim 40, wherein a circuit for generating the event signal is disposed in the semiconductor substrate.

44. The light detecting device of claim 43, wherein a circuit for generating the gradation signal is disposed in the semiconductor substrate.
